(19) United States
(12) Patent Application Publication
(10) Pub. No.: US 2025/0260413 A1
(43) Pub. Date: Aug. 14, 2025

(54) ANALOG DYNAMIC CALIBRATION OF SENSOR SIGNAL OFFSET FOR INDUCTIVE POSITION SENSOR, AND RELATED APPARATUSES AND METHODS

(71) Applicant: Microchip Technology Incorporated, Chandler, AZ (US)

(72) Inventor: Jebas Paul Daniel T, Tirunelveli (IN)

(21) Appl. No.: 19/049,808

(22) Filed: Feb. 10, 2025

(30) Foreign Application Priority Data
Feb. 14, 2024 (IN) 202441010001

(51) Int. Cl. H03M 1/10; G01D 5/20; G01D 18/00

(52) U.S. Cl. CPC H03M 1/1014; G01D 5/2086; G01D 18/008

(57) ABSTRACT

An apparatus comprises a position sensor circuit including an offset compensation circuitry to compensate for an offset voltage of a position signal. The offset compensation circuitry includes at least a first current digital-to-analog converter (DAC) and a second current DAC. The first current DAC includes a first reference input to receive a first input current that varies in response to changes in amplitude of an excitation signal. The first current DAC further includes first logic inputs to adjustably set to respective logic levels to produce a first output current to substantially match a predetermined constant current. The second current DAC includes a second reference input to receive the first output current from the first current DAC. The second current DAC further includes second logic inputs to adjustably set to respective logic levels to produce a second output current to compensate for the offset voltage.

### PRIORITY CLAIM

This application claims the benefit of the filing date of Republic of India Provisional Patent Application Ser. No. 20/244,1010001, filed Feb. 14, 2024, for “Analog Dynamic Calibration of Sensor Signal Offset for Inductive Position Sensor.”

### TECHNICAL FIELD

This invention relates generally to inductive position sensing. More specifically, some examples relate to electronic circuitry of non-contacting, planar linear or rotary inductive position sensors for detecting the position of a movable target, without limitation. Additionally, devices, systems, and methods are disclosed.

### BACKGROUND

If a coil of wire is placed in a changing magnetic field, a voltage will be induced at ends of the coil of wire. In a predictably changing magnetic field, the induced voltage will be predictable (based on factors including the area of the coil affected by the magnetic field and the degree of change of the magnetic field). It is possible to disturb a predictably changing magnetic field and measure a resulting change in the voltage induced in the coil of wire. Further, it is possible to create a sensor that measures movement of a disturber (or target) of a predictably changing magnetic field based on a change in a voltage induced in a coil of wire.

### BRIEF DESCRIPTION OF THE DRAWINGS

While this disclosure concludes with claims particularly pointing out and distinctly claiming specific examples, various features and advantages of examples within the scope of this disclosure may be more readily ascertained from the following description when read in conjunction with the accompanying drawings, in which:

FIG. 1 is a top down view of an inductive position sensor for position sensing of a target which is illustrated in a first (“start”) position, according to one or more examples;

FIG. 2 is a top down view of the inductive position sensor for position sensing of the target which is illustrated in a second (“end”) position, according to one or more examples;

FIG. 3 is a side view of the inductive position sensor of FIGS. 1 and 2, illustrating the target adjustably set at an airgap distance from multiple coils of the sensor;

FIG. 4 is a schematic diagram depicting a sensor integrated circuit (IC) containing a position sensor circuit operably coupled to the multiple coils, according to one or more examples;

FIG. 5 is a schematic block diagram of a system for an inductive position sensor, according to one or more examples;

FIG. 6 is a graph of examples of first (sine) position signals which may be exhibited in a signal path (e.g., channel 1 associated with a CL1 input pin) of the sensor IC, according to one or more examples;

FIG. 7 is a graph of examples of second (cosine) position signals which may be exhibited in a signal path (e.g., channel 2 associated with a CL2 input pin) of the sensor IC, according to one or more examples;

FIG. 8 is a schematic diagram of a system for an inductive position sensor, according to one or more examples;

FIG. 9 is a schematic diagram of a circuit portion of an excitation circuit and a gain control circuitry, according to one or more examples;

FIG. 10A is a schematic diagram of a circuit portion of a position sensor circuit including an offset compensation circuitry, according to one or more examples;

FIG. 10B is a schematic diagram of a circuit portion of a position sensor circuit including an offset compensation circuitry, according to one or more examples;

FIG. 11A is a schematic diagram of a circuit portion including the offset compensation circuitry operably coupled to a buffer output circuit (e.g., for channel 1 associated with CL1), according to one or more examples;

FIG. 11B is a schematic diagram of a circuit portion including the offset compensation circuitry operably coupled to a buffer output circuit (e.g., for channel 2 associated with CL2), according to one or more examples;

FIG. 12 is a system for calibrating an inductive position sensor for compensation of an offset voltage of a position signal of an inductive position sensor;

FIG. 13 is a flowchart of a method of calibrating an inductive position sensor for compensation of an offset voltage of a position signal, according to one or more examples;

FIG. 14 is a flowchart of a more general method of calibrating an inductive position sensor including a position sensor circuit of a sensor IC, according to one or more examples; and

FIG. 15 is a flowchart of another more general method of calibrating an inductive position sensor including a position sensor circuit of a sensor IC, according to one or more examples.

### DETAILED DESCRIPTION

In the following detailed description, reference is made to the accompanying drawings, which form a part hereof, and in which are shown, by way of illustration, specific examples of examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example of this disclosure to the specified components, steps, features, functions, or the like.

It will be readily understood that the components of the examples as generally described herein and illustrated in the drawing could be arranged and designed in a wide variety of different configurations. Thus, the following description of various examples is not intended to limit the scope of the present disclosure, but is merely representative of various examples. While the various aspects of the examples may be presented in drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be depicted by block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art would understand that information and signals may be represented using any of a variety of different technologies and techniques. For example, data, instructions, commands, information, signals, bits, and symbols that may be referenced throughout this description may be represented by voltages, currents, electromagnetic waves, magnetic fields or particles, optical fields or particles, or any combination thereof. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal. A person having ordinary skill in the art would appreciate that this disclosure encompasses communication of quantum information and qubits used to represent quantum information.

The various illustrative logical blocks, modules, and circuits described in connection with the examples disclosed herein may be implemented or performed with a general purpose processor, a special purpose processor, a Digital Signal Processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer is configured to execute computing instructions (e.g., software code) related to examples of the present disclosure.

The examples may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, or a subprogram, without limitation. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Inductive position sensors, including inductive linear position sensors or inductive angular position sensors, are useful. There are many advantages to inductive sensing technology, such as: contactless sensing; easily designed on a printed circuit board (PCB) with a metallic object as a target; suitable for harsh environments; cost-effective; resistant to magnetic fields; immunity to electromagnetic interference (EMI)/electromagnetic compatibility (EMC); and case of customization, without limitation.

When designing an inductive position sensor, an airgap between a target and multiple coils of the sensor may be adjusted and set to a desired level. While the sensor is operating, the airgap may even change at least to some extent according to a change in temperature. To compensate for the variation, front-end circuitry of a sensor IC may be designed to modulate an amplitude of an excitation signal according to the change in airgap.

In some approaches, the modulation of the excitation signal is performed in satisfaction of the trigonometric function, sine(x)²+cos(x)²=K, where K is a constant (e.g., 1). While performing such modulation, sensor offset is modulated in such a way that the offset and gain error information do not lie in the peak and the trough of the signal. Rather, the offset information is spread over a cycle that resembles the shape of the envelope of the excitation signal peak amplitude.

In some conventional approaches, a sensor IC includes an on-chip processor and analog-to-digital converters (ADCs), as well as a digital multi-point calibration algorithm for correction of the sensor offset. In such digital algorithmic approaches, considerable hardware is utilized to perform multiple floating-point multiplication and division of the algorithm. On the other hand, some sensor ICs are intended to be analog-only output ICs (e.g., for low cost solutions), which would involve an on-chip, analog-only calibration.

Apparatuses, methods, and systems to provide an on-chip, analog dynamic calibration for correcting non-linearities (e.g., sensor offset) in inductive position sensors are described herein. Dynamic calibration is a mechanism which corrects sensor offset “on-the-fly” during operation, for example, for changes in offset due to airgap, temperature, or other factor(s) (e.g., other factors that affect a coupling factor between target and sensor, and/or the excitation signal amplitude).

In one or more examples, what is provided is an offset compensation circuitry to dynamically compensate for the changes in sensor offset due to airgap, temperature, or other type of variation. In one or more examples, the offset compensation circuitry provides an analog mechanism to track excitation current or amplitude and, in response, changes a magnitude of the offset correction accordingly. In one or more examples, the offset compensation circuitry operates over temperature without substantial deviation. In one or more examples, the offset compensation circuitry compensates for aging variation in the sensor IC and/or its external components, and is not dependent on device mismatches.

In one or more examples, the technique is suitable for both open loop and closed loop applications without any change in calibration method. In one or more examples, a closed loop is used to control oscillator amplitude for keeping the signal swing constant, where the sensor offsets are corrected dynamically without use of any on-chip processor.

In one or more examples, analog dynamic compensation to compensate for changes in sensor offset are realized after a one-time calibration is performed at any suitable airgap height (e.g., a maximum airgap height or a target airgap height). Thus, in one or more examples, a one-time trimming in a calibration procedure at system setup is sufficient to accommodate for the offset compensation. In one or more examples, the one-time trimming may be performed at a maximum (possible) airgap height of the target, or at a desired airgap height of the target, as examples.

In one or more examples, the analog dynamic compensation provides for a low-cost solution, as the compensation does not rely upon or need a digital core in the circuitry. Accordingly, the circuitry for analog dynamic compensation may be provided in a sensor IC that excludes a digital core, on-chip processor or CPU, according to one or more examples (e.g., a sensor IC having analog-only outputs). In one or more examples, the offset compensation circuitry is suitable for use in a remote application, where signals are sent to an ECU of a vehicle and/or there is no microcontroller available on the same PCB or system.

In one or more examples, the offset compensation circuitry includes at least a first current digital-to-analog converter (DAC) and a second current DAC. The first current DAC includes a first reference input to receive a first input current that varies in response to changes in amplitude of an excitation signal. The first current DAC further includes first logic inputs to adjustably set to respective logic levels to produce a first output current to substantially match a predetermined constant current. The second current DAC includes a second reference input to receive the first output current from the first current DAC. The second current DAC further includes second logic inputs to adjustably set to respective logic levels to produce a second output current to compensate for offset voltage. In one or more examples, a tail current of an excitation circuit that varies according to amplitude of the excitation signal is utilized. A current mirror circuit is to mirror the tail current, and the mirrored tail current is used at the first reference input of the first current DAC.

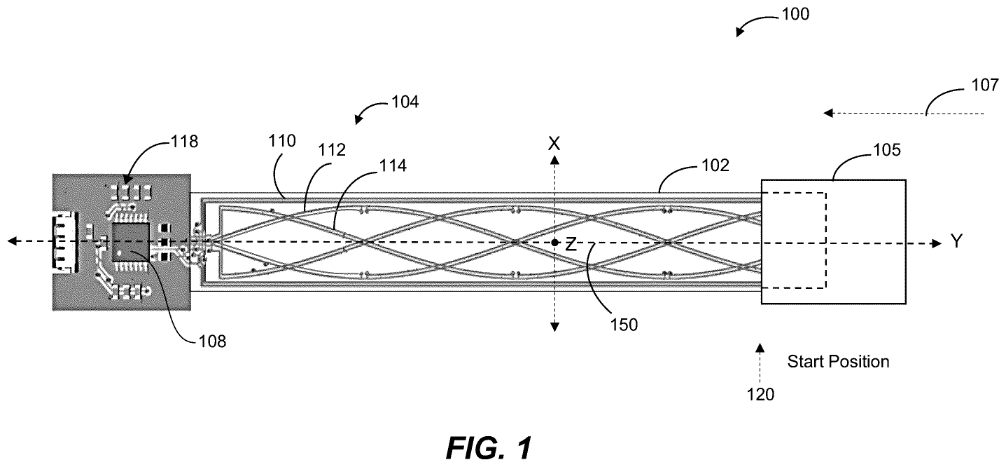

FIG. 1 is a top down view of an inductive position sensor 100 for position sensing of a target 105, according to one or more examples. Inductive position sensor 100 comprises a support structure 102 and multiple coils 104 on, or in, the support structure 102. Multiple coils 104 may include one or more excitation coils 110, a first sense coil 112, and a second sense coil 114. One or more excitation coils 110 (or oscillator coils) may be referred to as one or more primary coils, and first and second sense coils 112 and 114 may be referred to as secondary coils. In one or more examples, first sense coil 112 may be referred to as a sine coil and second sense coil 114 may be referred to as a cosine coil. In one or more examples, support structure 102 may be or include a substrate, such as a PCB. In one or more examples, one or more excitation coils 110, first sense coil 112, and second sense coil 114 may be laid out as conductive traces on, or in, support structure 102 (e.g., the PCB, in one or more planes or layers thereof), and referred to as planar coils of a non-contacting planar inductive position sensor.

Inductive position sensor 100 also includes a position sensor circuit 118 to process signals associated with multiple coils 104. In one or more examples, position sensor circuit 118 may be or include a sensor IC 108 including (e.g., most of) the position sensor circuit 118 for detecting the position of target 105.

In one or more examples, inductive position sensor 100 is a linear inductive position sensor. In a linear inductive position sensor, target 105 is movably positionable along a longitudinal axis 150 (i.e., along the Y-axis of an indicated three-dimensional coordinate axis system (X-Y-Z)) of support structure 102.

In FIG. 1, target 105 is shown positioned in a first position 120 (e.g., a start position) on a right or rightmost end of support structure 102. Target 105 may be movably positionable along longitudinal axis 150 in a first direction 107 (e.g., a right-to-left direction) towards the opposite end of support structure 102.

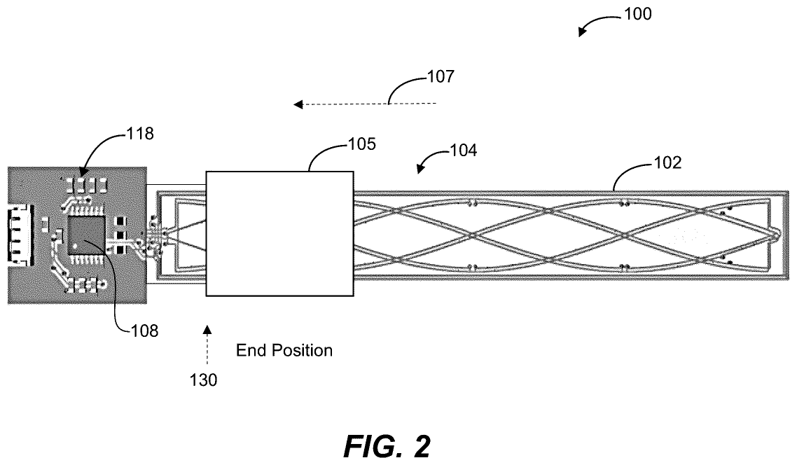

In FIG. 2, target 105 is shown positioned in a second position 130 (e.g., an end position) on a left or left-most end of support structure 102. In one or more other examples, the inductive position sensor may be a rotary inductive position sensor including a target that is rotatable.

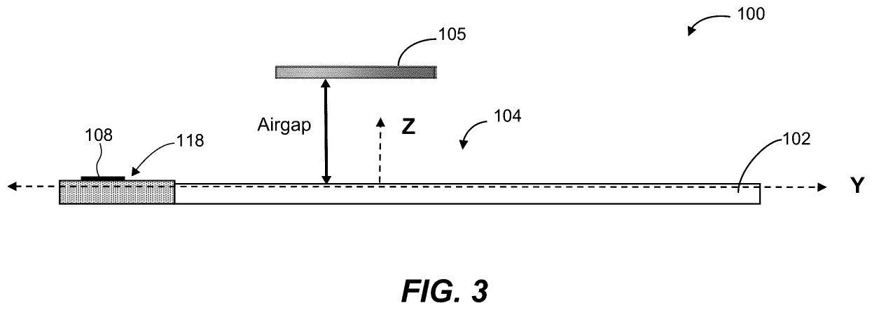

In general operation, one or more excitation coils 110 are excited with a high frequency signal (e.g., 5 MHz, without limitation) from sensor IC 108 to generate a varying magnetic field. The magnetic fields couple onto first and second sense coils 112 and 114 for generating first and second sense signals, respectively. Target 105 may be positioned over multiple coils 104 of inductive position sensor 100 (i.e., in the Z-direction of the coordinate system), adjustably set at a (e.g., fixed) distance from the coils, referred to as an airgap, indicated in a side view of inductive position sensor 100 in FIG. 3.

With reference to FIGS. 1, 2, and 3, target 105 may be made of a metal, such as a non-magnetic (conductive) metal, especially a highly-conductive metal, such as copper or aluminum, without limitation. In general, target 105 will disturb the generated magnetic field. When target 105 is present and is moved, it creates modulated cosine and sine waveforms which are received at the IC. The modulated cosine and sine signals may be de-modulated for generating first and second voltage position signals associated with the position of target 105. When a processor is included in sensor IC 108, or sensor IC 108 is coupled to microcontroller, the first and second voltage position signals can be used to calculate the position of target 105, for example, by taking an arctan2 function of the ratio of the signals.

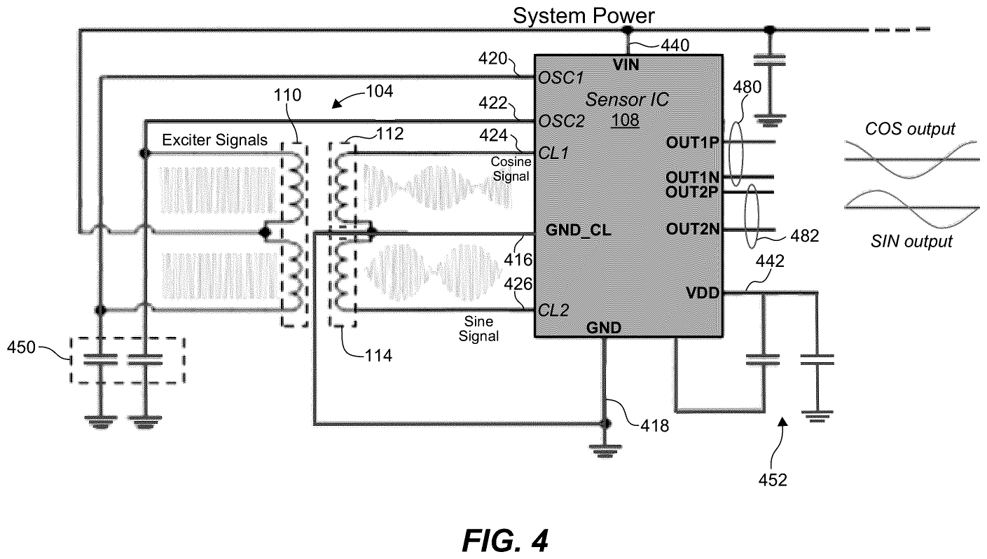

FIG. 4 is a schematic diagram depicting sensor IC 108 containing (e.g., most of) the position sensor circuit operably coupled to multiple coils 104, according to one or more examples. The position sensor circuit of sensor IC 108 is to perform signal processing to facilitate detection of a position (e.g., linear or angular/rotational) of a target in relation to multiple coils 104.

As depicted in FIG. 4, sensor IC 108 includes various input and output (I/O) pins, including a power supply input 440 (V_{IN}) and a ground input 418 (GND) to receive system power (e.g., power from a power source). Sensor IC 108 further includes a regulator voltage output 442 (V_{DD}) from an internal voltage regulator, which may provide power to electronic circuitry of the system (e.g., through one or more low dropout regulator (LDO) output capacitors 452).

In addition, sensor IC 108 includes I/O pins for coupling multiple coils 104 (e.g., on a PCB) to the position sensor circuit of sensor IC 108. More specifically, the I/O pins of sensor IC 108 include OSC1 and OSC2 output pins 420 and 422 coupled to an excitation circuit contained within sensor IC 108. OSC1 and OSC2 output pins 420 and 422 are to provide excitation signals to drive one or more excitation coils 110 to produce a time-varying magnetic field. OSC1 output pin 420 is coupled to a first end of one or more excitation coils 110 and to one of exciter capacitors 450 which is coupled to ground. OSC2 output pin 422 is coupled to a second end of one or more excitation coils 110 and to one of exciter capacitors 450 which is coupled to ground. A center tap is provided between one or more excitation coils 110 to the system power.

The I/O pins of IC 108 further include a CL1 input pin 424, a CL2 input pin 426, and a GNDCL input pin 416. First sense coil 112 has a first end coupled to CL1 input pin 424 and a second end coupled to GNDCL input pin 416. Second sense coil 114 has a first end coupled to CL2 input pin 426 and a second end coupled to GNDCL input pin 416. CL1 input pin 424 and GNDCL input pin 416 are to receive a first sense signal from first sense coil 112 induced from the time-varying magnetic field. CL2 input pin 426 and GNDCL input pin 416 are to receive a second sense signal from second sense coil 114 also induced from the time-varying magnetic field. The first and second sense signals are modulated according to changes in position of the target.

In one or more examples, the position sensor circuit contained in sensor IC 108 includes at least an analog front-end (AFE) (not shown in FIG. 4). In one or more examples, the AFE operates to filter, demodulate, and output demodulated cosine and sine signals. Output pins of sensor IC 108 include cosine and sine signal outputs, for example, OUT1P and OUT1N output pins 480 for outputting the cosine signal, and OUT2P and OUT2N output pins 482 for outputting the sine signal.

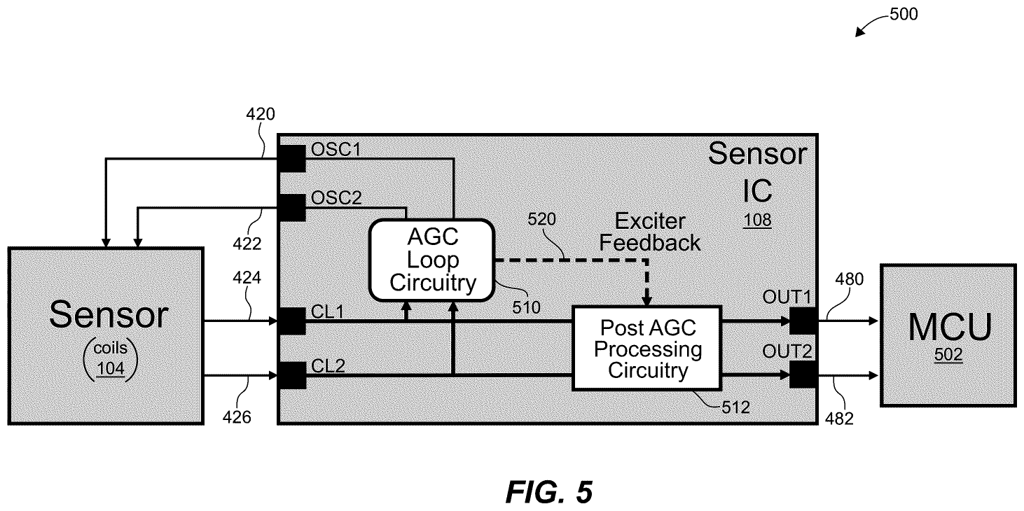

FIG. 5 is a schematic block diagram of a system 500 for an inductive position sensor, according to one or more examples. In FIG. 5, system 500 includes a sensor (i.e., including multiple coils 104 of FIGS. 1 and 2), sensor IC 108 containing a position sensor circuit coupled to multiple coils 104 and to a microcontroller unit (MCU) 502. More specifically, sensor IC 108 includes OSC1 and OSC2 output pins 420 and 422 coupled to multiple coils 104 (i.e., one or more excitation coils of the sensor), CL1 and CL2 input pins 424 and 426 coupled to multiple coils 104 (i.e., the first and the second sense coils of the sensor), and OUT1 and OUT2 output pins 480 and 482 coupled to MCU 502.

In general, there are two kinds of offsets associated with the inductive position sensor: (1) offset from the PCB; and (2) offset from static metal. Both of these offsets are directly proportional to the amplitude of the excitation signal. There is no DC offset in the sensor (i.e., no excitation signal-independent offset). The gain error does not change with respect to the airgap. In the inductive position sensor, the following relation exists: A*(1+A_{GE})*(V_{off}+Sin(θ)), where A_{GE} represents the gain error and V_{off} represents the offset error.

Sensor IC 108 of FIG. 5 depicts a general circuit arrangement associated with offset compensation, according to one or more examples. In one or more examples, the general circuit arrangement of sensor IC 108 includes an automatic gain control (AGC) loop circuitry 510 and a post-AGC processing circuitry 512 for compensation of sensor offset voltages.

In FIG. 5, AGC loop circuitry 510 is operably coupled to the receive signal paths (e.g., associated with CL1 and CL2 input pins 424 and 426) and to an excitation circuit of sensor IC 108 (e.g., coupled to OUT1 and OUT2 output pins 420 and 422). AGC loop circuitry 510 is adapted to provide an AGC loop that is regulated according to the trigonometry condition, CL1²+CL2²=K. Such regulation ensures that the peak-to-peak of the CL1 and CL2 signals are always the same in satisfaction of the condition.

While regulating the AGC loop, AGC loop circuitry 510 applies the same condition to the sensor offset voltages, modifying the CL1 and CL2 waveforms in such a way as to satisfy the condition. The sensor offsets vary with airgap, temperature, and so on. Note that the sensor offsets are modulated in such a way that the offset and gain error information do not lie in respective peaks and troughs of the signals. Rather, the offset information is spread over a cycle that resembles the shape of the envelope of the excitation signal peak amplitude.

In one or more examples, post-AGC processing circuitry 512 of sensor IC 108 compensates for the sensor offsets and outputs the respective position signals from sensor IC 108. Post-AGC processing circuitry 512 utilizes feedback signals 520 (e.g., “exciter feedback”) from the excitation circuit of AGC loop circuitry 510 to compensate for the sensor offsets. The respective position signals output at OUT1 and OUT2 output pins 480 and 482 therefore do not have the offset information in their respective peaks and troughs.

MCU 502 (or ECU) is coupled to OUT1 and OUT2 output pins 480 and 482 to receive the respective position signals from sensor IC 108. MCU 502 is to calculate the position of the target based on the signals (e.g., based on an arctan2 function of the ratio of the signals). In one or more examples, MCU 502 does not need to perform any compensation or correction for offset voltage, as the sensor offset and post-AGC IC offsets are canceled in sensor IC 108. MCU 502 can measure any change in the post AGC IC offset and gain error (e.g., due to temperature drift) and correct it using peak and valley measurements.

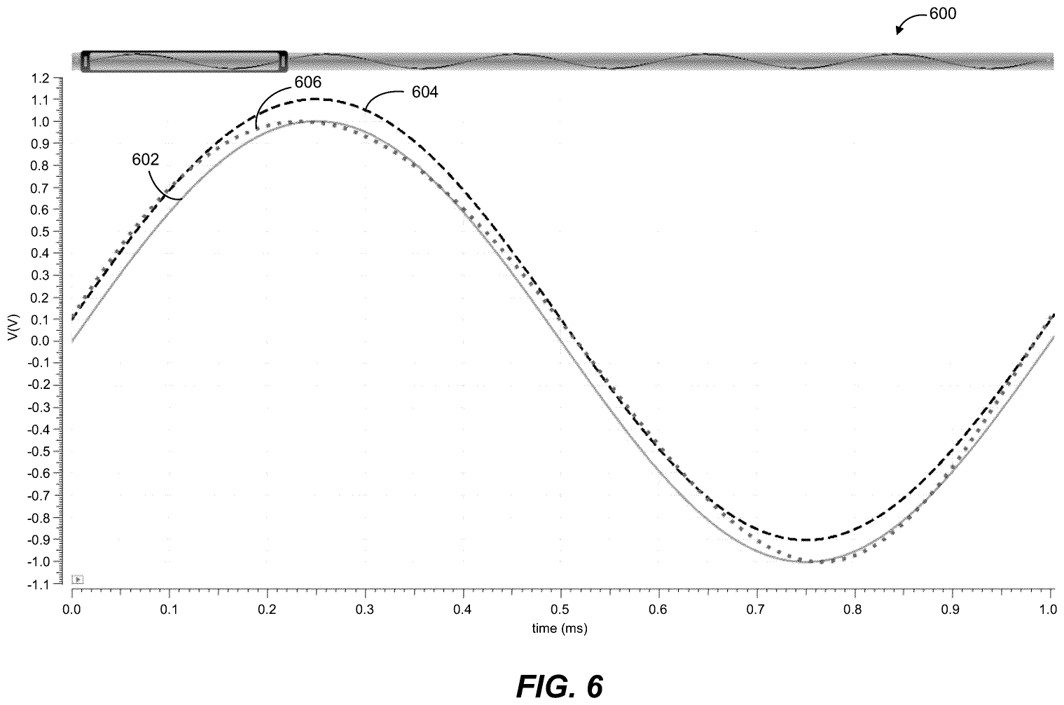

FIG. 6 is a graph 600 of examples of first (sine) position signals which may be exhibited in the signal path of the channel 1 associated with the CL1 input pin, according to one or more examples. In FIG. 6, a first position signal 602 is an ideal sine signal without offset; a first errored position signal 604 is an ideal sine signal with offset (e.g., 100 mV); and a first other errored position signal 606 is a closed-loop modulated sine signal with the offset (e.g., 100 mV).

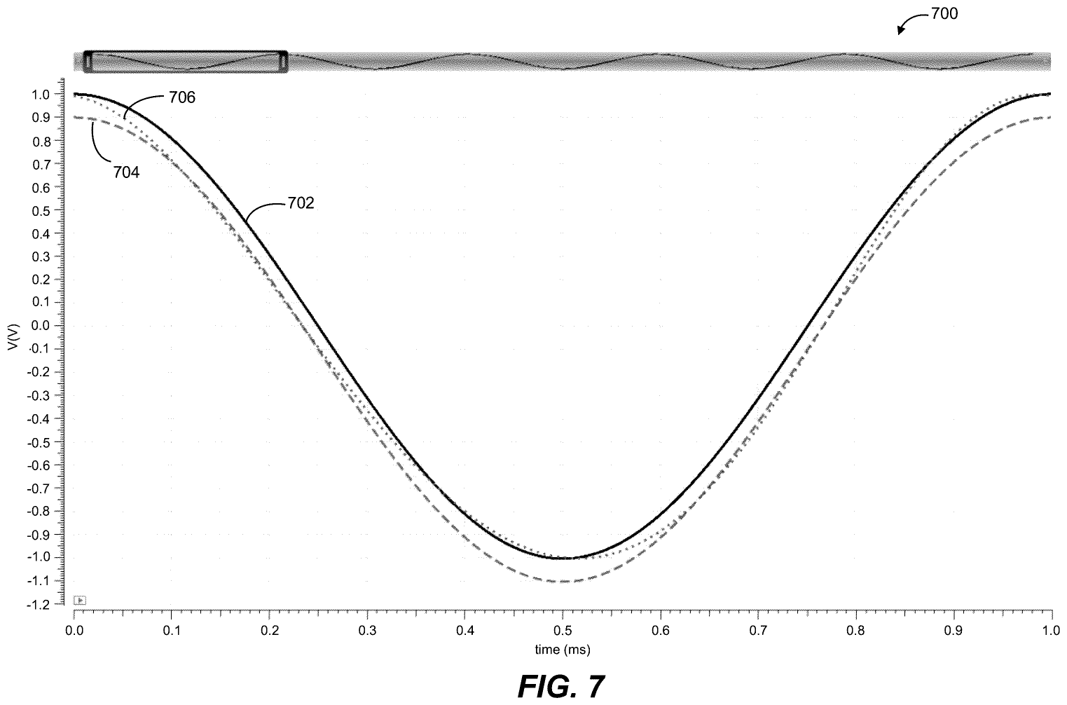

FIG. 7 is a graph 700 of examples of second (cosine) position signals which may be exhibited in the signal path of the channel 2 associated with the CL2 input pin, according to one or more examples. In FIG. 7, a second position signal 702 is an ideal cosine sense signal without offset; a second errored position signal 704 is an ideal cosine sense signal with offset (e.g., −100 mV); and a second other errored signal 706 is a closed-loop modulated cosine sense signal with the offset (e.g., −100 mV).

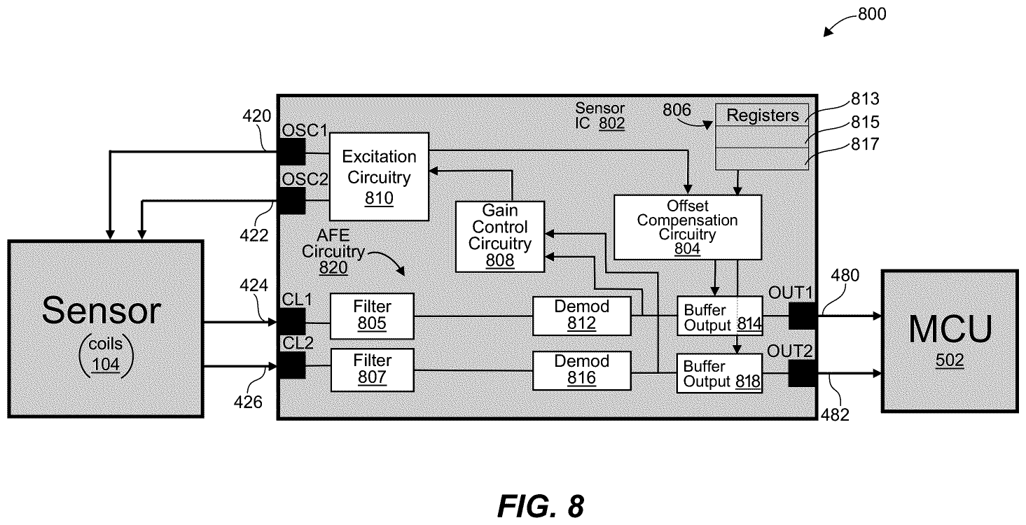

FIG. 8 is a schematic diagram of a system 800 for an inductive position sensor, according to one or more examples. In FIG. 8, system 800 includes a sensor (i.e., including multiple coils 104 of FIGS. 1 and 2), a sensor IC 802 containing a position sensor circuit coupled to multiple coils 104 and to MCU 502 (FIG. 5). More specifically, sensor IC 802 includes OSC1 and OSC2 output pins 420 and 422 coupled to multiple coils 104 (i.e., one or more excitation coils of the sensor), CL1 and CL2 input pins 424 and 426 coupled to multiple coils 104 (i.e., the first and the second sense coils of the sensor), and OUT1 and OUT2 output pins 480 and 482 coupled to MCU 502.

In one or more examples, the position sensor circuit of sensor IC 802 includes an excitation circuit 810, an AFE 820, a gain control circuitry 808, and an offset compensation circuitry 804. For processing a modulated first sinusoidal sense signal from the first sense coil (at CL1 input pin 424), AFE 820 includes a first AFE circuitry including a filter circuit 805 (e.g., an EMI filter circuit), a demodulator circuit 812, and a buffer output circuit 814. For processing a modulated second sinusoidal sense signal from the second sense coil (at CL2 input pin 426), AFE 820 further includes a second AFE circuitry including a filter circuit 807 (e.g., an EMI filter circuit), a demodulator circuit 816, and a buffer output circuit 818. After being filtered and demodulated, and processed at the output buffers, first and second position signals (e.g., indicating a position of the target) are provided at OUT1 and OUT2 output pins 480 and 482 of sensor IC 802. In general, offset compensation circuitry 804 is to compensate for offset voltages of the first and the second position signals at buffer output circuits 814 and 818.

In example operation, excitation circuit 810 generates one or more excitation signals (e.g., at OSC1 and OSC2 output pins 420 and 422) (e.g., at a high frequency, e.g., 5 MHZ, without limitation) used to drive the one or more excitation coils (e.g., at multiple coils 104) to produce a varying magnetic field around the one or more excitation coils. The varying magnetic field induces first and second sinusoidal sense signals in the first and the second sense coils, respectively. Prior to sensor operation, a target of the inductive position sensor is adjusted and set to a desired airgap distance from multiple coils 104. Accordingly, the varying magnetic field may be disturbed in accordance with a linear position of a target (e.g., or an angular position of the target if the sensor is an inductive angular position sensor), for modulating the first and second sinusoidal sense signals in the first and the second sense coils. The modulated first and second sinusoidal sense signals from the first and the second sense coils are received at CL1 and CL2 input pins 424 and 426 of sensor IC 802.

In one or more examples, the one or more excitation coils include a first excitation coil and a second excitation coil. Here, excitation circuit 810 generates a first excitation signal in the first excitation coil and a second excitation signal in the second excitation coil (e.g., provided at OSC1 and OSC2 output pins 420 and 422) for producing the varying magnetic field which induces the first and the second sense signals in the first and the second sense coils, respectively. In one or more examples, the first excitation signal is substantially 180° out-of-phase with the second excitation signal.

Responsive to the excitation signals, AFE 820 receives and processes the modulated first and second sinusoidal sense signals. In particular, the modulated first sinusoidal sense signal (at CL1 input pin 424) is filtered through filter circuit 805, demodulated by demodulator circuit 812 to generate the first position signal, buffered at buffer output circuit 814, and output at OUT1 output pin 480. The modulated second sinusoidal sense signal (at CL2 input pint 426) is filtered through filter circuit 807, demodulated by demodulator circuit 816 to generate the second position signal, buffered at buffer output circuit 818, and output at OUT2 output pin 482.

Gain control circuitry 808 is to adjust the amplitude of the excitation signal(s) at least partially based on an amplitude of the first and/or the second position signals. Gain control circuitry 808 implements an AGC loop that is regulated according to the trigonometry condition, CL1²+CL2²=K, ensuring that the peak-to-peak of the signals (e.g., always or continuously) satisfy the above condition. Gain control circuitry 808 applies the same condition to the sensor offset voltages, which vary with airgap, temperature, and so on.

Offset compensation circuitry 804 compensates for offset voltages of the first and the second position signals at buffer output circuits 814 and 818, respectively. In one or more examples, offset compensation circuitry 804 interfaces with (e.g., programmable) registers 806 of sensor IC 802. Registers 806 are used store digital values to adjust for the level of offset compensation. In one or more examples, the digital values are adjustable and set (e.g., set to a fixed digital value) in registers 806 during a calibration procedure with the inductive position sensor. In one or more examples of FIG. 8, registers 806 include one or more first registers 813, one or more second registers 815, and one or more third registers 817.

In one or more examples, when the position sensor circuit of sensor IC 802 includes a processor (e.g., a central processing unit (CPU) configured to execute machine-executable code), it may calculate the angular position of the target, at least partially based on the first and the second position signals. In one or more preferred examples, the position sensor circuit of sensor IC 802 excludes the CPU configured to execute machine-executable code. Here, MCU 502 (or, e.g., an ECU) may receive the first and the second position signals at the OUT1 and OUT2 output pins 480 and 482, respectively, and calculate the angular position of the target at least partially based on the first and the second position signals (e.g., based on the arctan2 function, without limitation). Offset compensation circuitry 804 compensates for the offset voltages in the first and the second position signals received and processed at MCU 502 or the ECU.

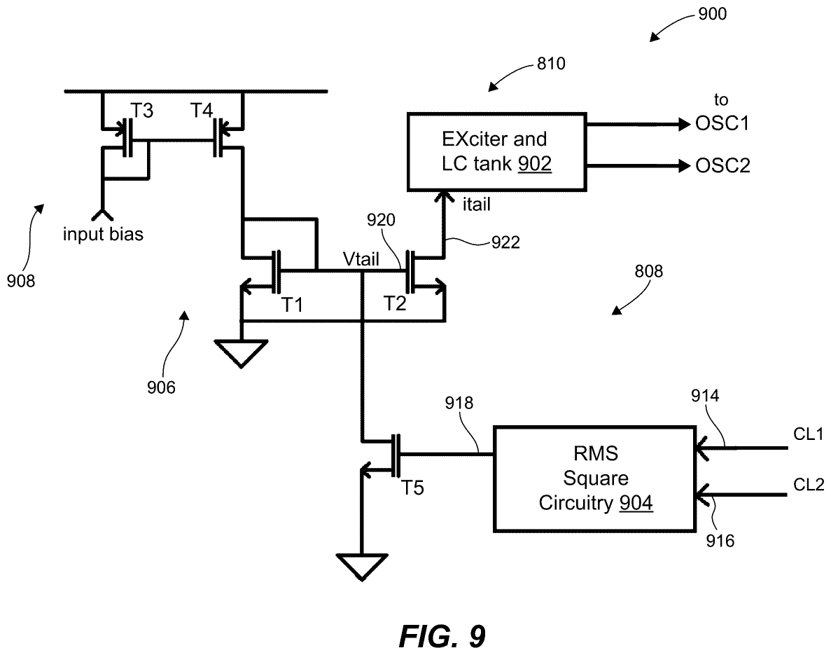

In the above-described arrangement without the CPU, sensor IC 802 (e.g., with or without any of the additional circuitry shown and described in relation to FIGS. 9, 10A, 10B, 11A, and/or 11B) may be considered and/or referred to as an “analog only IC” adapted for dynamically correcting for changes in sensor offset (e.g., due to airgap variation).

FIG. 9 is a schematic diagram of a circuit portion 900 of excitation circuit 810 and gain control circuitry 808, according to one or more examples. In FIG. 9, excitation circuit 810 includes an exciter and inductor-capacitor (LC) tank circuit 902, a drive circuit 906 coupled to exciter and LC tank circuit 902, and a biasing circuit 908 coupled to drive circuit 906. Drive circuit 906 includes a pair of transistors T1 and T2 used to actively drive exciter and LC tank circuit 902. Biasing circuit 908 includes a pair of transistors T3 and T4 including respective sources coupled to a voltage reference and respective gates coupled to each another. The gate of transistor T3 is coupled to its drain to receive an input bias. The pair of transistors T1 and T2 of drive circuit 906 includes respective sources coupled to a ground reference and respective gates coupled to each another and to the drain of transistor T1. Gain control circuitry 808 includes a root mean square (RMS) circuitry 904. First and second position/sense signals from the first and the second sense coils at CL1 and CL2 input pins are received at inputs 914 and 916 of RMS circuitry 904. An output 918 of RMS circuitry 904 is coupled to a gate of transistor T5, which has a drain coupled to drive circuit 906 at the gates of transistors T1 and T2 and a source coupled to the ground reference. In the described arrangement, at drive circuit 906, a tail voltage Vₜₐᵢₗ is generated at the gate terminals of transistors T1 and T2, and correspondingly, a tail current Iₜₐᵢₗ is generated at the drain terminal (at a node 922 or output of drive circuit 906) of transistor T2. The tail current Iₜₐᵢₗ is input to exciter and LC tank circuit 902 for generating an excitation signal(s) (or oscillator signal(s)) at a resonant frequency (or frequencies) of exciter and LC tank circuit 902. The outputs of exciter and LC tank circuit 902 are coupled to OSC1 and OSC2output pins of the sensor IC.

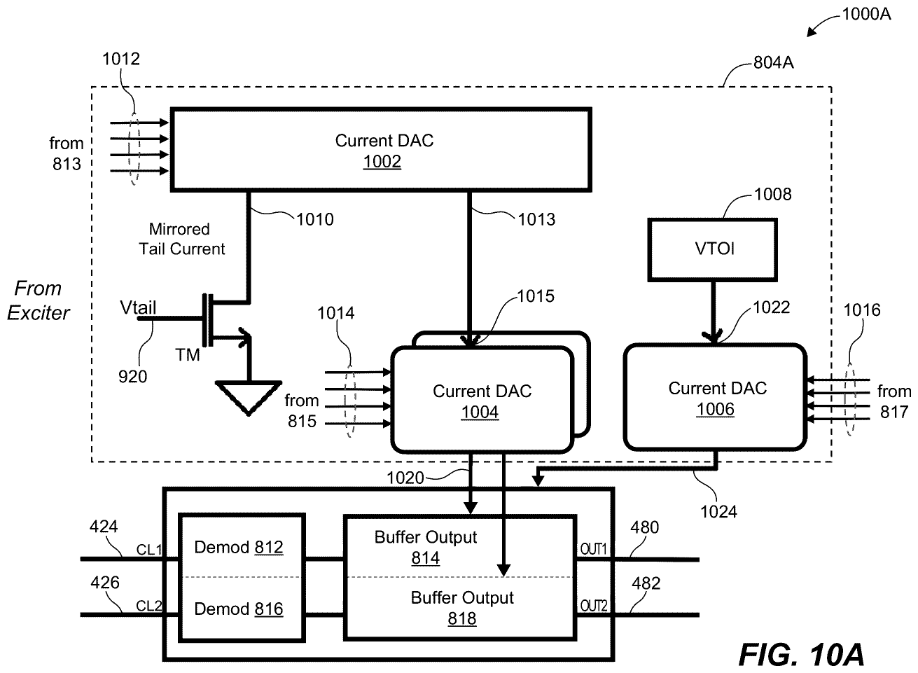

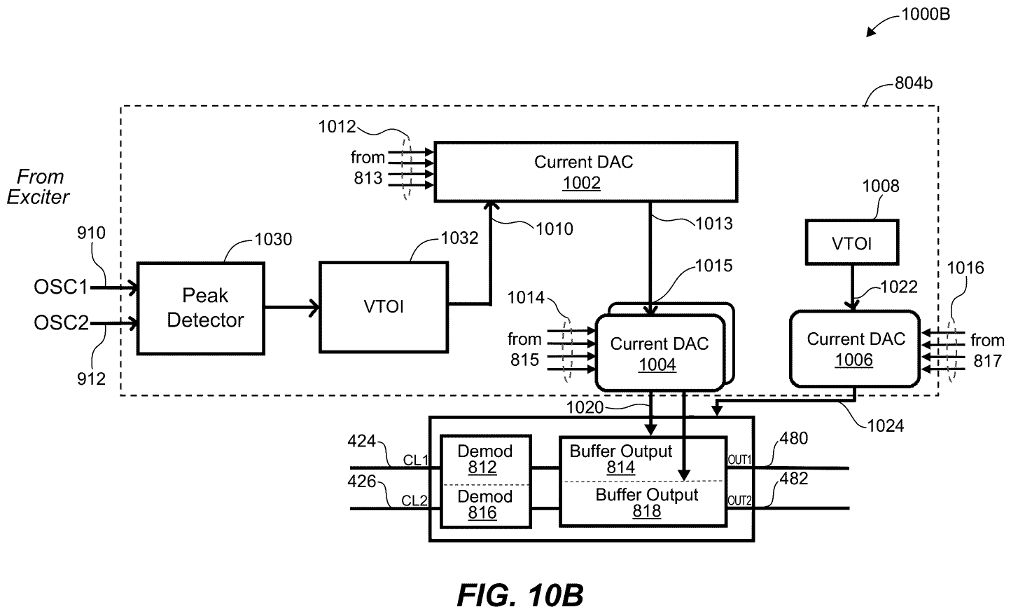

FIG. 10A is a schematic diagram of a circuit portion 1000A of a position sensor circuit including an offset compensation circuitry 804a, according to one or more examples. Offset compensation circuitry 804a of FIG. 10A is one example of offset compensation circuitry 804 of FIG. 8. In one or more examples, offset compensation circuitry 804a of FIG. 10A may allow for a one-time calibration step or procedure at system setup for calibration of the sensor at any suitable (fixed) airgap and temperature.

In one or more examples, offset compensation circuitry 804a includes at least two current DACs. In FIG. 10A, offset compensation circuitry 804a includes a current DAC 1002, a current DAC 1004, and a current DAC 1006. Each one of current DACs 1004, 1004, and 1006 includes a reference input, logic inputs, and an output. For example, current DAC 1002 includes a reference input 1010, logic inputs 1012, and an output 1013. Current DAC 1004 includes a reference input 1015, logic inputs 1014, and an output 1020. Current DAC 1006 includes a reference input 1022, logic inputs 1016, and an output 1024.

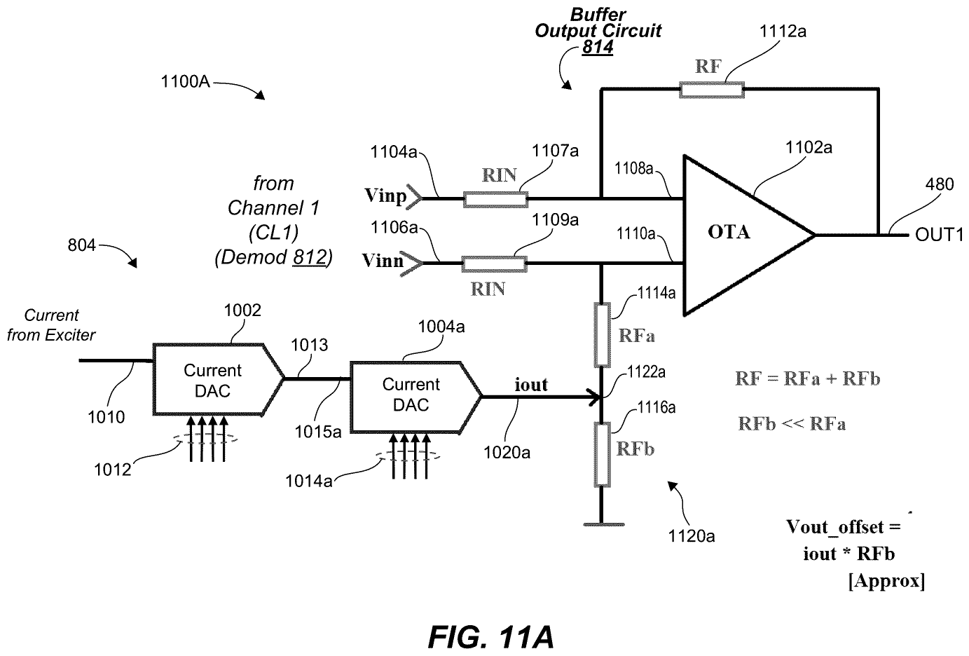

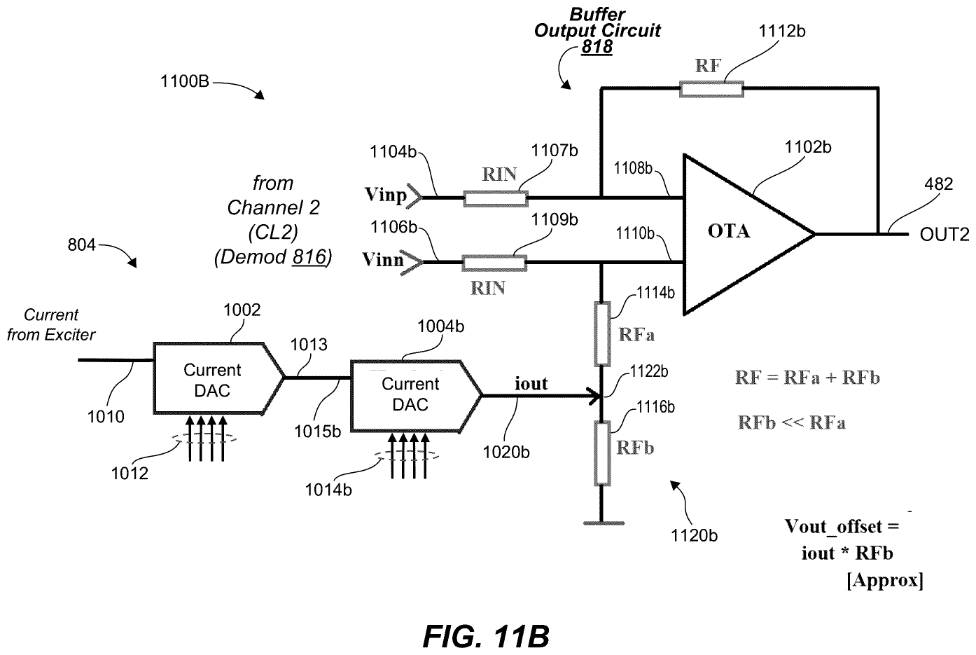

In one or more examples, current DAC 1002 is configured for a low resolution (“coarse”) adjustment of offset and current DAC 1004 is configured for a high resolution (“fine”) adjustment of offset. In one or more examples, a dedicated current DAC for “fine adjustment” is utilized for each channel (e.g., channel 1 associated with CL1, and channel 2 associated with CL2), and therefore two current DACs may be provided in place of current DAC 1004 (e.g., current DAC 1004a of FIG. 11A for channel 1 associated with CL1, and current DAC 1004b of FIG. 11B for channel 2 associated with CL2, described later below).

Current DAC 1002 includes reference input 1010 to receive an input current that varies in response to changes in amplitude of the excitation signal. In offset compensation circuitry 804a of FIG. 10A, the input current at reference input 1010 is a mirrored tail current of the tail current from the excitation circuit (e.g., excitation circuit 810 of FIG. 8). In one or more examples, the tail current from the excitation circuit is mirrored at reference input 1010 of current DAC 1002 through a current mirror circuit. In one or more examples, the current mirror circuit includes at least a transistor T_{M} having a gate coupled to node 920 from excitation circuit 810 (e.g., node 920 at which the tail voltage Vₜₐᵢₗ is present).

In current DAC 1002, an output current produced at output 1013 is at least partially based on the input current at reference input 1010 and adjustably set logic levels of logic inputs 1012 of current DAC 1002. Offset compensation circuitry 804a may include or utilize one or more first registers (e.g., one or more first registers 813 of FIG. 8), operably coupled to logic inputs 1012 of current DAC 1002, in which to program and store one or more first digital values. The one or more first digital values adjustably set the respective logic levels of logic inputs 1012 of current DAC 1002 to produce, at output 1013, the output current.

More specifically, logic inputs 1012 of current DAC 1002 are adjustably set (e.g., at system setup, for programming and storing the one or more first digital values in the one or more first registers) to respective logic levels to produce, at output 1013, an output current to substantially match a predetermined constant current. In one or more examples, the predetermined constant current is set to be less than the (mirrored) tail current. In one or more further examples, the predetermined constant current is set to be at least one (1) order, two (2) orders, or three (3) orders of magnitude less than the (mirrored) tail current.

Current DAC 1004 includes reference input 1015 to receive the output current (e.g., the predetermined constant current) from current DAC 1002. In current DAC 1004, the output current produced at output 1020 is at least partially based on the input current at reference input 1015 and the adjustably set logic levels of logic inputs 1014 of current DAC 1004. Offset compensation circuitry 804a may include or utilize one or more second registers (e.g., one or more second registers 815 of FIG. 8), operably coupled to logic inputs 1014 of current DAC 1004, in which to program and store one or more second digital values. The one or more second digital values adjustably set the respective logic levels of logic inputs 1014 of current DAC 1004 to produce, at output 1020, the output current.

More specifically, current DAC 1004 includes logic inputs 1014 to be adjustably set (e.g., at system setup, for programming and storing the one or more second digital values in the one or more second registers) to respective logic levels to produce, at output 1020, an output current to compensate for an offset voltage of a position signal (e.g., a first position signal for channel 1 associated with CL1). In one or more examples, output 1020 of current DAC 1004 is operably coupled to an input of buffer output circuit 814, or an amplifier thereof, to achieve the offset compensation (e.g., for channel 1 associated with CL1). In one or more further examples, an additional output of an additional current DAC is operably coupled to an input of buffer output circuit 818, or an amplifier thereof, to compensate for an additional offset voltage of a second position signal (e.g., for channel 2 associated with CL2).

Thus, as the position sensor circuit operates to adjust, using its gain control circuitry (e.g., gain control circuitry 808 of FIGS. 8 and 9), the peak amplitude of the excitation voltage according to airgap variation of the target, the tail current of the excitation circuit will vary according to the airgap variation. As the current mirror circuit mirrors this varied tail current, i.e., an excitation signal-dependent current, a lesser variation of the tail current is accurately tracked at output 1013 of current DAC 1002.

In one or more examples, offset compensation circuitry 804a includes a voltage-to-current (VTOI) converter 1008, and current DAC 1006 includes reference input 1022 to receive a VTOI current from VTOI converter 1008. In current DAC 1006, an output current produced at output 1024 is at least partially based on the input current at reference input 1022 and adjustably set logic levels of logic inputs 1016 of current DAC 1006. Offset compensation circuitry 804a may include or utilize one or more third registers (e.g., one or more third registers 817 of FIG. 8), operably coupled to logic inputs 1016 of current DAC 1006, in which to program and store one or more third digital values. The one or more third digital values adjustably set the respective logic levels of logic inputs 1016 of current DAC 1006 to produce, at output 1024, the output current. More specifically, logic inputs 1016 of current DAC 1006 are adjustably set (e.g., at system setup, programming and storing the one or more third digital values in the one or more third registers) to respective logic levels to produce, at output 1024, an output current to trim IC offset of the sensor IC.

When circuit portion 1000A of FIG. 10A is included as part of a sensor IC without a CPU (e.g., without a CPU for a digital multi-point calibration algorithm to correct sensor offset), the sensor IC may be considered and/or referred to as an “analog-only IC” adapted for dynamically correcting for changes in sensor offset due to airgap variation (e.g., using additional circuitry of FIGS. 11A and 11B).

FIG. 10B is a schematic diagram of a circuit portion 1000B of a position sensor circuit including an offset compensation circuitry 804b, according to one or more examples. Offset compensation circuitry 804b of FIG. 10B is another example of offset compensation circuitry 804 of FIG. 8. In one or more examples, offset compensation circuitry 804b of FIG. 10B may allow for a one-time calibration step or procedure at system setup for calibration of the sensor at any suitable (fixed) airgap and temperature. Like circuit portion 1000A of FIG. 10A, when circuit portion 1000B of FIG. 10B is included as part of a sensor IC without a CPU, the sensor IC may be considered and/or referred to as an analog-only IC adapted for dynamically correcting for changes in sensor offset due to airgap variation.

Offset compensation circuitry 804b of FIG. 10B is substantially the same as offset compensation circuitry 804a of FIG. 10A, without use of the mirrored tail current from the excitation circuit through the current mirror circuit. In one or more examples, offset compensation circuitry 804b of FIG. 10B includes a peak detector 1030 and a VTOI converter 1032. Peak detector 1030 includes inputs 910 and 912 coupled to excitation signal output(s) (OSC1, OSC2) of the excitation circuit (e.g., excitation circuit 810 of FIG. 9). Peak detector 1030 is to detect peak voltages of the excitation signal(s). VTOI converter 1032 is to convert the peak voltages of the excitation signal(s) into the input current at reference input 1010 of current DAC 1002.

In one or more examples, offset compensation circuitry 804b of FIG. 10B may operate effectively even when the excitation circuit saturates, as the generated current is amplitude-dependent. Thus, if the excitation signal saturates (e.g., due to lesser or higher saturation power or Rp), the compensation utilized in FIG. 10B may have better performance than that utilized in FIG. 10A. On the other hand, offset compensation circuitry 804b of FIG. 10B utilizes additional components than the circuitry of FIG. 10A, and the temperature variation of these additional components may affect performance.

FIG. 11A is a schematic diagram of a circuit portion 1100A including offset compensation circuitry 804 operably coupled to buffer output circuit 814 (e.g., for channel 1 associated with CL1), according to one or more examples.

FIG. 11B is a schematic diagram of a circuit portion 1100B including offset compensation circuitry 804 operably coupled to buffer output circuit 818 (e.g., for channel 2 associated with CL2), according to one or more examples.

As is apparent from FIGS. 11A and 11B, the circuitry for each one of channels 1 and 2 may be substantially the same according to one or more examples, where current DAC 1002 is shared for both channels, and where current DAC 1004a (FIG. 11A) is dedicated to channel 1 (CL1) and current DAC 1004b (FIG. 11B) is dedicated to channel 2 (CL2).

In FIG. 11A, an output of demodulator circuit 812 of channel 1 associated with CL1 is coupled to differential inputs 1104a and 1106a of buffer output circuit 814 (e.g., Vᵢₙₚ and Vᵢₙₙ, respectively). Buffer output circuit 814 includes an amplifier 1102a. In one or more examples, amplifier 1102a is an operational transductance amplifier (OTA). Amplifier 1102a includes differential inputs 1108a and 1110a operably coupled to the output of the demodulator circuit 812, via resistors 1107a and 1109a, at differential inputs 1104a and 1106a, respectively. Each one of resistors 1107a and 1109a has a resistance RI. Amplifier 1102a also includes an output (e.g., coupled to output pin 480) which is coupled to one of differential inputs 1108a and 1110a (i.e., differential input 1108a) of amplifier 1102a via at least a feedback resistor 1112a having a resistance RF.

Buffer output circuit 814 includes a voltage divider circuit 1120a including at least a resistor 1114a and a resistor 1116a coupled in series. Voltage divider circuit 1120a is coupled between the other one of differential inputs 1108a and 1110a (i.e., differential input 1110a) of amplifier 1102a and a reference voltage (e.g., a ground voltage). Resistor 1114a has a resistance RFa and resistor 1116a has a resistance RFb. In one or more examples, resistance RFa+resistance RFb=resistance RF, where resistance RFb>>resistance RFa. In offset compensation circuitry 804, output 1020a of current DAC 1004a is coupled to a node 1122a at which resistors 1114a and 1116a of voltage divider circuit 1120a are series coupled.

Current DAC 1002 includes logic inputs 1012 to be adjustably set to respective logic levels to produce at output 1013 a first output current to substantially match a predetermined constant current. In one or more examples, the predetermined constant current is set to be less than the (mirrored) tail current or exciter current. In one or more further examples, the predetermined constant current is set to be at least one (1) order, two (2) orders, or three (3) orders of magnitude less than the (mirrored) tail current or exciter current.

Current DAC 1004a includes reference input 1015a to receive the first output current from current DAC 1002. Current DAC 1004a includes logic inputs 1014a to be adjustably set to respective logic levels to produce at output 1020a a second output current (e.g., iout as indicated in the figure) to compensate for the offset voltage of the position signal (e.g., for channel 1 associated with CL1). More particularly, current DAC 1004a includes logic inputs 1014a to be adjustably set to the respective logic levels to produce the second output current that produces an adjustment offset voltage V_{out_offset} at node 1122a to substantially match or cancel the offset voltage at the output of amplifier 1102a of buffer output circuit 814. In one or more examples, the adjustment offset voltage V_{out_offset}˜iout*RFb.

In FIG. 11B, an output of demodulator circuit 816 of channel 2 associated with CL2 is coupled to differential inputs 1104b and 1106b of buffer output circuit 818 (e.g., Vᵢₙₚ and Vᵢₙₙ, respectively). Buffer output circuit 818 includes an amplifier 1102b. In one or more examples, amplifier 1102b is an OTA. Amplifier 1102b includes differential inputs 1108b and 1110b operably coupled to the output of the demodulator circuit 816, via resistors 1107b and 1109b, at differential inputs 1104b and 1106b, respectively. Each one of resistors 1107b and 1109b has a resistance R_{IN}. Amplifier 1102b also includes an output (coupled to output pin 482) which is coupled to one of differential inputs 1108b and 1110b (i.e., differential input 1108b) of amplifier 1102b via at least a feedback resistor 1112b having a resistance RF.

Buffer output circuit 818 includes a voltage divider circuit 1120b including at least a resistor 1114b and a resistor 1116b coupled in series. Voltage divider circuit 1120b is coupled between the other one of differential inputs 1108b and 1110b (i.e., differential input 1110b) of amplifier 1102b and a reference voltage (e.g., a ground voltage). Resistor 1114b has a resistance RFa and resistor 1116b has a resistance RFb. Again, in one or more examples, resistance RFa+resistance RFb=resistance RF, where resistance RFb>>resistance RFa. In offset compensation circuitry 804, output 1020b of current DAC 1004b is coupled to a node 1122b at which resistors 1114b and 1116b of voltage divider circuit 1120b are series coupled.

In FIG. 11B, as similarly described in relation to FIG. 11A, current DAC 1002 includes logic inputs 1012 to be adjustably set to respective logic levels to produce at output 1013 a first output current to substantially match a predetermined constant current. In one or more examples, the predetermined constant current is set to be less than the (mirrored) tail current or exciter current. In one or more further examples, the predetermined constant current is set to be at least one (1) order, two (2) orders, or three (3) orders of magnitude less than the (mirrored) tail current or exciter current.

Current DAC 1004b includes reference input 1015b to receive the first output current from current DAC 1002. Current DAC 1004b includes logic inputs 1014b to be adjustably set to respective logic levels to produce at output 1020b a second output current (e.g., iout as indicated in the figure), to compensate for the offset voltage of the position signal (e.g., for channel 2 associated with CL2). More particularly, current DAC 1004b includes logic inputs 1014b to be adjustably set to the respective logic levels to produce the second output current that produces an adjustment offset voltage V_{out_offset} at node 1122b to substantially match or cancel the offset voltage at the output of amplifier 1102b of buffer output circuit 818. In one or more examples, the adjustment offset voltage V_{out_offset}˜iout*RFb.

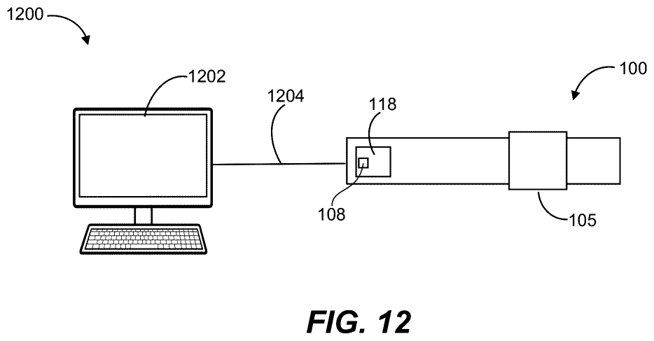

FIG. 12 is a system 1200 for calibrating an inductive position sensor for compensation of an offset voltage of a position signal of an inductive position sensor.

System 1200 includes a computing device 1202 and a programming interface 1204 connected to inductive position sensor 100. Programming interface 1204 includes a communication interface for data communications between computing device 1202 and position sensor circuit 118. The data communications between computing device 1202 and position sensor circuit 118 are used in a calibration procedure for compensating of the offset voltage. In one or more examples, the communication interface is a serial peripheral interface (SPI). More particularly, computing device 1202 is used to program registers of position sensor circuit 118 of sensor IC 108 for the offset voltage compensation. In addition, computing device 1202 may include user interface components for input entry and output display (e.g., a monitor or visual display, a keyboard or keypad, and so on). In one or more examples, computing device 1202 may operate to present a graphical user interface (GUI) for input entry (e.g., entry of adjustment values and/or adjustment commands) and/or output display (e.g., display of feedback and/or measurements).

In a calibration procedure, a user may interact with computing device 1202 for adjustably setting and programming, via programming interface 1204, digital values in registers of position sensor circuit 118 (e.g., sensor IC 108). One or more first registers of position sensor circuit 118 are operably coupled to first logic inputs of the first current DAC, and one or more second registers of position sensor circuit 118 are operably coupled to second logic inputs of the second current DAC. In one or more examples, the adjustably set digital values, or values corresponding thereto, may be displayed in the display or GUI. In one or more examples, measurements responsive to the outputs of the first and the second current DACs, or values corresponding thereto, which are based on the adjustably set digital values, may be displayed in the display or GUI.

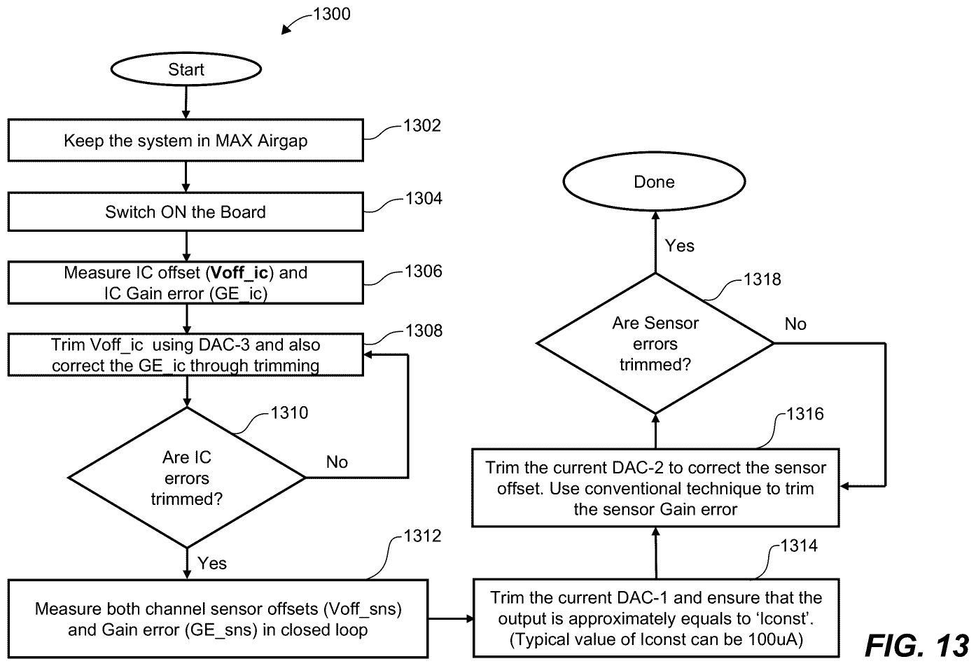

FIG. 13 is a flowchart of a method 1300 of calibrating an inductive position sensor for compensation of an offset voltage of a position signal, according to one or more examples. In one or more examples of FIG. 13, a computing device is used to perform the calibration procedure with the position sensor circuit via a programming interface (e.g., in system 1200 of FIG. 12). In one or more examples, the programming interface includes or involves a GUI for a user to interface with the computing device for facilitating the calibration procedure.

Beginning at a start block, at an act 1302, a target of the inductive position sensor is set at a maximum airgap height relative to the coils of the inductive position sensor. In one or more examples, the target is set at the maximum airgap height in the calibration procedure in order to prevent an output saturation condition which might otherwise occur (e.g., in cases where the target is set at a relatively greater height in normal operation). In one or more alternative examples, the target is set at a desired airgap height to substantially match a desired, intended airgap height used in normal operation.

At an act 1304, the inductive position sensor is switched on. At an act 1306, an IC offset (V_{off_ic}) and an IC gain error (GE_ic) are measured. At an act 1308, the IC offset (V_{off_ic}) is trimmed using current DAC-3 (e.g., current DAC 1006 of FIGS. 10A and 10B), and the IC gain error (GE_ic) is also corrected through trimming. At an act 1310, the trimming of V_{off_ic} and GE_ic is continued in act 1308 until all of the IC errors are trimmed.

At an act 1312, voltage offsets (V_{off_sns}) for both channels (i.e., CL1 and CL2) and gain error (GE_sns) in closed loop are measured. At an act 1314, current DAC-1 (e.g., current DAC 1002 of FIGS. 10A and 10B) is trimmed to ensure that the output approximately matches a predetermined constant current, referred to as I_{const}. In a specific, non-limiting example, I_{const}=100 μA. Accordingly, the exciter current (e.g., typically on the order of mA) is accurately scaled to a suitable current for offset compensation (e.g., typically on the order of uA or nA).

At an act 1316, current DAC-2 (e.g., current DAC 1004a and/or current DAC 1004b of FIGS. 10A and 10B) is then trimmed to correct the sensor offset (e.g., for each channel, CL1 and CL2). The gain error may be trimmed using any suitable conventional or other technique. The trimming of the sensor offset is continued until (e.g., all) the sensor error is trimmed. At an act 1318, the trimming is continued in act 1316 until all of the sensor errors are trimmed.

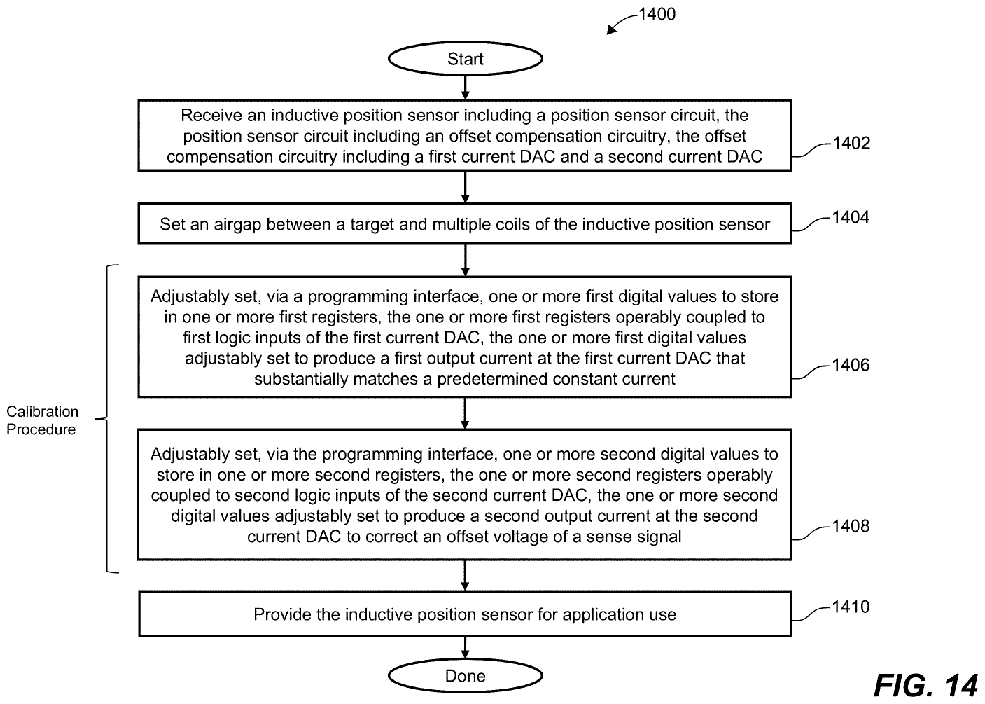

FIG. 14 is a flowchart of a more general method 1400 of calibrating an inductive position sensor including a position sensor circuit of a sensor IC, according to one or more examples. In one or more examples of FIG. 14, a computing device is used to perform the calibration procedure with the position sensor circuit via a programming interface (e.g., in system 1200 of FIG. 12). In one or more examples, the programming interface includes or involves a GUI for a user to interface with the computing device for facilitating the calibration procedure.

At an act 1402, an inductive position sensor including a position sensor circuit is received. In one or more examples, the inductive position sensor to be calibrated includes a support structure and multiple coils on, or in, the support structure. The multiple coils may include one or more excitation coils and first and second sense coils. The position sensor circuit includes an offset compensation circuitry to compensate for an offset voltage of a position signal of the inductive position sensor. The offset compensation circuitry includes at least a first current DAC and a second current DAC.

At an act 1404, an airgap between a target and the multiple coils of the inductive position sensor is adjusted and set. In one or more examples, the target of the inductive position sensor is set at a maximum airgap height relative to the multiple coils of the inductive position sensor. In one or more examples, the target is set at the maximum airgap height in order to prevent an output saturation condition which might otherwise occur (e.g., in cases where the target is set at a relatively greater height in normal operation). In one or more alternative examples, the target is set at a desired airgap height to substantially match a desired, intended airgap height used in normal operation.

In the calibration procedure, at an act 1406, one or more first digital values are adjustably set via a programming interface. The one or more first digital values are to store in one or more first registers of the position sensor circuit. The first current DAC includes a first reference input to receive a first input current that varies in response to changes in amplitude of an excitation signal. The one or more first registers are operably coupled to first logic inputs of the first current DAC, and the one or more first digital values are adjustably set to produce a first output current at the first current DAC that substantially matches a predetermined constant current. Accordingly, the first input current (e.g., the exciter current, on the order of mA) may be accurately scaled to a suitable first output current for offset compensation (e.g., on the order of uA or nA). In one or more examples, measurements of the first output current, or values corresponding thereto, may be read or otherwise communicated in association with the adjustments to the one or more first digital values (e.g., for the user to view to make determinations for appropriate adjustments). The first output current is received at a second reference input of the second current DAC.

Continuing the calibration procedure, at an act 1408, one or more second digital values are adjustably set via the programming interface. The one or more second digital values are to store in one or more second registers of the position sensor circuit. The one or more second registers are operably coupled to second logic inputs of the second current DAC. The one or more second digital values are adjustably set to produce a second output current at the second current DAC to compensate for the offset voltage of the position signal. In one or more examples, measurements of the second output current, or values corresponding thereto, may be read or otherwise communicated in association with the adjustments to the one or more second digital values (e.g., for the user to view to make determinations for appropriate adjustments).

After the calibration procedure, at an act 1410, the inductive position sensor is provided for application use. The position sensor circuit is operated in a normal operating mode to process signals using the offset compensation.

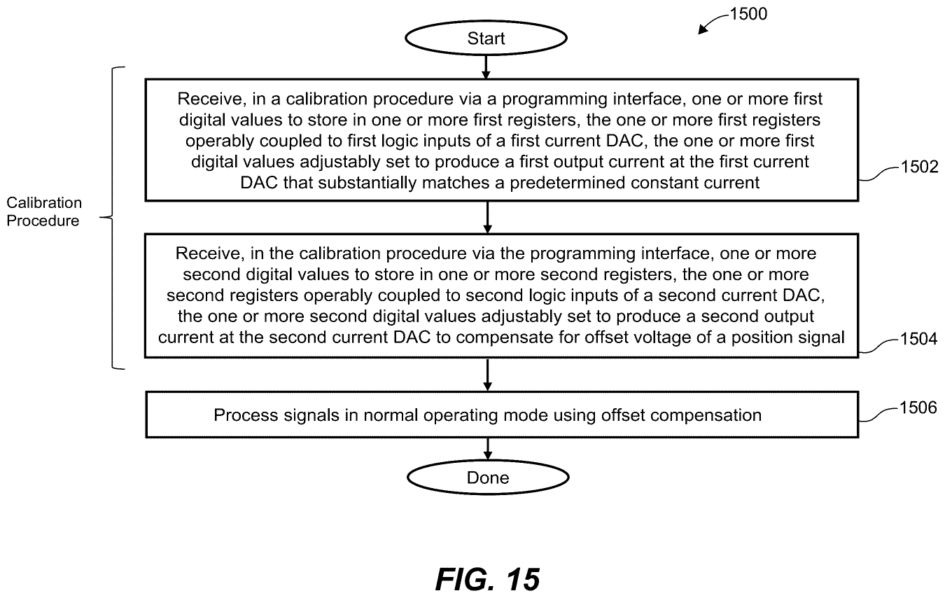

FIG. 15 is a flowchart of another more general method 1500 of calibrating an inductive position sensor including a position sensor circuit of a sensor IC, according to one or more examples. In one or more examples of FIG. 15, a computing device is used to perform a calibration procedure with the position sensor circuit via a programming interface (e.g., in system 1200 of FIG. 12). In one or more examples, the programming interface includes or involves a GUI for a user to interface with the computing device for facilitating the calibration procedure.

In one or more examples, the inductive position sensor to be calibrated includes a support structure and multiple coils on, or in, the support structure. The multiple coils include one or more excitation coils and first and second sense coils. The position sensor circuit includes an offset compensation circuitry to compensate for an offset voltage of a position signal of the inductive position sensor. The offset compensation circuitry includes at least a first current DAC and a second current DAC.

In the calibration procedure, at an act 1502, one or more first digital values are received via the programming interface. The one or more first digital values are stored in one or more first registers of the position sensor circuit. The first current DAC includes a first reference input to receive a first input current that varies in response to changes in amplitude of an excitation signal. The one or more first registers are operably coupled to first logic inputs of the first current DAC. The one or more first digital values are adjustably set to produce a first output current at the first current DAC that substantially matches a predetermined constant current. In one or more examples, the first input current (e.g., the exciter current, on the order of mA) is accurately scaled to a suitable first output current for offset compensation (e.g., on the order of uA or nA). In one or more examples, measurements of the first output current, or values corresponding thereto, may be communicated responsive to adjustments to the one or more first digital values (e.g., for the user to view to make determinations for appropriate adjustments). The first output current is received at a second reference input of the second current DAC.

Continuing the calibration procedure, at an act 1504, one or more second digital values are received via the programming interface. The one or more second digital values are stored in one or more second registers of the position sensor circuit. The one or more second registers are operably coupled to second logic inputs of the second current DAC. The one or more second digital values are adjustably set to produce a second output current at the second current DAC to compensate for the offset voltage of the position signal. In one or more examples, measurements of the second output current, or values corresponding thereto, may be communicated responsive to adjustments to the one or more second digital values (e.g., for the user to view to make determinations for appropriate adjustments).

After the calibration procedure, at an act 1506, the inductive position sensor is provided for application use. The position sensor circuit operates in a normal operating mode to process signals of the inductive position sensor using the offset compensation.

In one or more examples of FIG. 15, prior to the calibration procedure, an airgap between the target and the multiple coils of the inductive position sensor may be adjusted and set. In one or more examples, the target is set at a maximum airgap height (e.g., to avoid an output saturation condition). In one or more other examples, the target is set to a desired target airgap height. In the position sensor circuit, an amplitude of an excitation signal is adjusted responsive to the setting of the airgap.

In one or more examples of FIG. 15, a tail current of an excitation circuit is mirrored as the first input current at the first reference input of the first current DAC. In one or more alternative examples of FIG. 15, peak voltages of the excitation signal are detected, and the peak voltages are converted into the first input current at the first reference input of the first current DAC.

In one or more examples of FIG. 15, the position sensor circuit including the offset compensation circuitry is provided to further include: an excitation circuit to generate the excitation signal to drive one or more excitation coils, the excitation signal to produce a varying magnetic field around the one or more excitation coils for inducing a sinusoidal sense signal in a sense coil, the varying magnetic field disturbed in accordance with a position of a target which modulates the sinusoidal sense signal; an analog front-end circuit to receive and process the modulated sinusoidal sense signal; a demodulator circuit to demodulate the modulated sinusoidal sense signal to generate the position signal at an output, the position signal having the offset voltage; a gain control circuitry, the gain control circuitry to adjust the amplitude of the excitation signal at least partially based on an amplitude of the position signal; a buffer output circuit comprising an amplifier, the amplifier including differential inputs operably coupled to the output of the demodulator circuit, the amplifier including an output coupled to one of the differential inputs via at least a feedback resistor; a voltage divider circuit including at least first and second resistors coupled in series, the voltage divider circuit coupled between the other one of the differential inputs of the amplifier and a reference voltage; and the output of the second DAC coupled to a node at which the first and the second resistors of the voltage divider circuit are series coupled. In one or more specific examples, the position sensor circuit including the offset compensation circuitry is provided in an IC, where the IC excludes a central processing unit configured to execute machine-executable code.

It will be appreciated by those of ordinary skill in the art that functional elements of examples disclosed herein (e.g., functions, operations, acts, processes, and/or methods) may be implemented in any suitable hardware, software, firmware, or combinations thereof. In one or more examples, some or all portions of the functional elements disclosed herein may be performed by hardware specially programmed for carrying out the functional elements.

As used in the present disclosure, the terms “module” or “component” may refer to specific hardware implementations to perform the actions of the module or component and/or software objects or software routines that may be stored on and/or executed by general purpose hardware (e.g., computer-readable media, processing devices, etc.) of the computing system. In some examples, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different sub-combinations of some of the elements. For example, the phrase “A, B, C, D, or combinations thereof” may refer to any one of A, B, C, or D; the combination of each of A, B, C, and D; and any sub-combination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.,” or “one or more of A, B, and C, etc.,” is used, in general such a construction is intended to include A alone, B alone, C alone, A and B together, A and C together, B and C together, or A, B, and C together, etc.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

While the present disclosure has been described herein with respect to certain illustrated examples, those of ordinary skill in the art will recognize and appreciate that the present invention is not so limited. Rather, many additions, deletions, and modifications to the illustrated and described examples may be made without departing from the scope of the invention as hereinafter claimed along with their legal equivalents. In addition, features from one example may be combined with features of another example while still being encompassed within the scope of the invention as contemplated by the inventor.

A non-exhaustive, non-limiting list of examples follows. Not each of the examples listed below is explicitly and individually indicated as being combinable with all others of the examples listed below and examples discussed above. It is intended, however, that these examples are combinable with all other examples unless it would be apparent to one of ordinary skill in the art that the examples are not combinable.

Example 1: An apparatus comprising: a position sensor circuit including an offset compensation circuitry to compensate for an offset voltage of a position signal, the offset compensation circuitry comprising: a first current digital-to-analog converter (DAC), the first current DAC including a first reference input to receive a first input current that varies in response to changes in amplitude of an excitation signal of the position sensor circuit, the first current DAC including first logic inputs to be adjustably set to respective logic levels to produce a first output current to substantially match a predetermined constant current; and a second current DAC, the second current DAC including a second reference input to receive the first output current from the first current DAC, the second current DAC including second logic inputs to be adjustably set to respective logic levels to produce a second output current to compensate for the offset voltage.

Example 2: The apparatus according to Example 1, wherein: the position sensor circuit including the offset compensation circuitry comprises: a buffer output circuit comprising an amplifier, the amplifier including differential inputs to receive the position signal and an output to output the position signal, the output of the amplifier coupled to one of the differential inputs via at least a feedback resistor; and an output of the second DAC to produce the second output current, the output of the second DAC operably coupled to the other one of the differential inputs of the amplifier of the buffer output circuit.

Example 3: The apparatus according to any of Examples 1 and 2, wherein: the position sensor circuit including the offset compensation circuitry comprises: a voltage divider circuit including at least first and second resistors coupled in series, the voltage divider circuit coupled between the other one of the differential inputs of the amplifier and a reference voltage; and the output of the second DAC coupled to a node at which the first and the second resistors of the voltage divider circuit are series coupled.

Example 4: The apparatus according to any of Examples 1 through 3, wherein: the second current DAC includes the second logic inputs to be adjustably set to the respective logic levels to produce the second output current that produces an adjustment offset voltage at the node to substantially match or cancel the offset voltage at the output of the amplifier of the buffer output circuit.

Example 5: The apparatus according to any of Examples 1 through 4, wherein the amplifier of the buffer output circuit comprises an operational transconductance amplifier.

Example 6: The apparatus according to any of Examples 1 through 5, wherein: the position sensor circuit including the offset compensation circuitry comprises: one or more first registers in which to program and store one or more first digital values, the one or more first registers operably coupled to the first logic inputs of the first current DAC, the one or more first digital values in the one or more first registers to adjustably set the respective logic levels of the first logic inputs of the first current DAC to produce the first output current; and one or more second registers in which to program and store one or more second digital values, the one or more second registers operably coupled to the second logic inputs of the second current DAC, the one or more second digital values in the one or more second registers to adjustably set the respective logic levels of the second logic inputs of the second current DAC to produce the second output current.

Example 7: The apparatus according to any of Examples 1 through 6, wherein: the position sensor circuit comprises: an excitation circuit to generate the excitation signal to drive one or more excitation coils, the excitation signal to produce a varying magnetic field around the one or more excitation coils for inducing a sinusoidal sense signal in a sense coil, the varying magnetic field disturbed in accordance with a position of a target which modulates the sinusoidal sense signal; an analog front-end circuit to receive and process the modulated sinusoidal sense signal; and a demodulator circuit to demodulate the modulated sinusoidal sense signal to generate the position signal at an output, the output of the demodulator circuit coupled to the differential inputs of the amplifier of the buffer output circuit.

Example 8: The apparatus according to any of Examples 1 through 7, wherein: the position sensor circuit comprises: a gain control circuitry, the gain control circuitry to adjust the amplitude of the excitation signal at least partially based on an amplitude of the position signal.

Example 9: The apparatus according to any of Examples 1 through 8, wherein: the position sensor circuit including the offset compensation circuitry comprises: a current mirror circuit, the current mirror circuit coupled to the excitation circuit and the first current DAC, the current mirror circuit to mirror a tail current of the excitation circuit as the first input current at the first reference input of the first current DAC.

Example 10: The apparatus according to any of Examples 1 through 9, wherein: the position sensor circuit including the offset compensation circuitry comprises: a peak detector, the peak detector to detect peak voltages of the excitation signal; and a voltage-to-current converter, the voltage-to-current converter to convert the peak voltages of the excitation signal into the first input current at the first reference input of the first current DAC.

Example 11: The apparatus according to any of Examples 1 through 10, comprising: an integrated circuit (IC) including the position sensor circuit, the output of the amplifier of the buffer output circuit coupled to an output pin of the IC.

Example 12: The apparatus according to any of Examples 1 through 11, wherein the IC excludes a central processing unit configured to execute machine-executable code.

Example 13: An apparatus comprising: an integrated circuit (IC) including a position sensor circuit comprising: an excitation circuit to generate an excitation signal to drive one or more excitation coils, the excitation signal to produce a varying magnetic field around the one or more excitation coils for inducing a sinusoidal sense signal in a sense coil, the varying magnetic field disturbed in accordance with a position of a target which modulates the sinusoidal sense signal; an analog front-end circuit to receive and process the modulated sinusoidal sense signal; a demodulator circuit to demodulate the modulated sinusoidal sense signal to generate a position signal at an output; a buffer output circuit comprising an amplifier, the amplifier including differential inputs operably coupled to the output of the demodulator circuit, the amplifier including an output coupled to one of the differential inputs via at least a feedback resistor, the output coupled to an output pin of the IC; an offset compensation circuitry to compensate for an offset voltage of the position signal, the offset compensation circuitry comprising: a first current digital-to-analog converter (DAC), the first current DAC including a first reference input to receive a first input current that varies in response to changes in amplitude of the excitation signal, the first current DAC including first logic inputs to be adjustably set to respective logic levels to produce a first output current to substantially match a predetermined constant current; and a second current DAC, the second current DAC including a second reference input to receive the first output current from the first current DAC, the second current DAC including an output operably coupled to the other one of the differential inputs of the amplifier of the buffer output circuit, the second current DAC including second logic inputs to be adjustably set to respective logic levels to produce a second output current at the output to compensate for the offset voltage.

Example 14: The apparatus according to Example 13, wherein: the offset compensation circuitry comprises: a voltage divider circuit including at least first and second resistors coupled in series, the voltage divider circuit coupled between the other one of the differential inputs of the amplifier of the buffer output circuit and a reference voltage; and the output of the second DAC coupled to a node at which the first and the second resistors of the voltage divider circuit are series coupled.

Example 15: The apparatus according to any of Examples 13 and 14, wherein: the offset compensation circuitry comprises: one or more first registers in which to program and store one or more first digital values, the one or more first registers operably coupled to the first logic inputs of the first current DAC, the one or more first digital values in the one or more first registers to adjustably set the respective logic levels of the first logic inputs of the first current DAC to produce the first output current; one or more second registers in which to program and store one or more second digital values, the one or more second registers operably coupled to the second logic inputs of the second current DAC, the one or more second digital values in the one or more second registers to adjustably set the respective logic levels of the second logic inputs of the second current DAC to produce the second output current; wherein in the first current DAC, the first output current is produced at least partially based on the first input current at the first reference input and the adjustably set logic levels of the first logic inputs of the first current DAC; and wherein in the second current DAC, the second output current is produced at least partially based on the first output current at the second reference input and the adjustably set logic levels of the second logic inputs of the second current DAC.

Example 16: The apparatus according to any of Examples 13 through 15, wherein: the position sensor circuit comprises: a gain control circuitry, the gain control circuitry to adjust the amplitude of the excitation signal at least partially based on an amplitude of the position signal.

Example 17: The apparatus according to any of Examples 13 through 16, wherein: the offset compensation circuitry comprises: a current mirror circuit, the current mirror circuit coupled to the excitation circuit and the first current DAC, the current mirror circuit to mirror a tail current of the excitation circuit as the first input current at the first reference input of the first current DAC.

Example 18: The apparatus according to any of Examples 13 through 17, wherein: the offset compensation circuitry comprises: a peak detector, the peak detector to detect peak voltages of the excitation signal; and a voltage-to-current converter, the voltage-to-current converter to convert the peak voltages of the excitation signal into the first input current.

Example 19: The apparatus according to any of Examples 13 through 18, wherein the IC excludes a central processing unit configured to execute machine-executable code.

Example 20: A method comprising: at a position sensor circuit for an inductive position sensor, the position sensor circuit including an offset compensation circuitry to compensate for an offset voltage of a position signal of the inductive position sensor, the offset compensation circuitry including at least a first current digital-to-analog converter (DAC) and a second current DAC, the first current DAC including a first reference input to receive a first input current that varies in response to changes in amplitude of an excitation signal of the position sensor circuit, receiving, in a calibration procedure via a programming interface, one or more first digital values to store in one or more first registers of the offset compensation circuitry, the one or more first registers operably coupled to first logic inputs of the first current DAC, the one or more first digital values adjustably set to produce a first output current at the first current DAC that substantially matches a predetermined constant current, the first output current received at a second reference input of the second current DAC; and receiving, in the calibration procedure via the programming interface, one or more second digital values to store in one or more second registers of the offset compensation circuitry, the one or more second registers operably coupled to second logic inputs of the second current DAC, the one or more second digital values adjustably set to produce a second output current at the second current DAC to compensate for the offset voltage.

Example 21: The method according to Example 20, the method comprising: prior to the calibration procedure, setting an airgap between a target and multiple coils of the inductive position sensor.

Example 22: The method according to any of Examples 20 and 21, comprising: at the position sensor circuit, providing, in the calibration procedure via the programming interface, measurements of the first output current, or values corresponding thereto, responsive to adjustments to the one or more first digital values; and providing, in the calibration procedure via the programming interface, measurements of the second output current, or values corresponding thereto, responsive to adjustments to the one or more second digital values.

Example 23: The method according to any of Examples 20 through 22, comprising: providing the position sensor circuit including the offset compensation circuitry, comprising: an excitation circuit to generate the excitation signal to drive one or more excitation coils, the excitation signal to produce a varying magnetic field around the one or more excitation coils for inducing a sinusoidal sense signal in a sense coil, the varying magnetic field disturbed in accordance with a position of a target which modulates the sinusoidal sense signal; an analog front-end circuit to receive and process the modulated sinusoidal sense signal; a demodulator circuit to demodulate the modulated sinusoidal sense signal to generate the position signal at an output, the position signal having the offset voltage; a gain control circuitry, the gain control circuitry to adjust the amplitude of the excitation signal at least partially based on an amplitude of the position signal; a buffer output circuit comprising an amplifier, the amplifier including differential inputs operably coupled to the output of the demodulator circuit, the amplifier including an output coupled to one of the differential inputs via at least a feedback resistor; a voltage divider circuit including at least first and second resistors coupled in series, the voltage divider circuit coupled between the other one of the differential inputs of the amplifier and a reference voltage; and the output of the second current DAC coupled to a node at which the first and the second resistors of the voltage divider circuit are series coupled.

Example 24: The method according to any of Examples 20 through 23, wherein the position sensor circuit including the offset compensation circuitry is provided in an integrated circuit (IC), the IC excluding a central processing unit configured to execute machine-executable code.

Example 25: The method according to any of Examples 20 through 24, comprising: at the position sensor circuit including the offset compensation circuitry, mirroring a tail current of the excitation circuit as the first input current at the first reference input of the first current DAC.

Example 26: The method according to any of Examples 20 through 25, wherein: at the position sensor circuit including the offset compensation circuitry, detecting peak voltages of the excitation signal; and converting the peak voltages of the excitation signal into the first input current at the first reference input of the first current DAC.

What is claimed is:

1. An apparatus comprising:
a position sensor circuit including an offset compensation circuitry to compensate for an offset voltage of a position signal, the offset compensation circuitry comprising:
a first current digital-to-analog converter (DAC), the first current DAC including a first reference input to receive a first input current that varies in response to changes in amplitude of an excitation signal of the position sensor circuit, the first current DAC including first logic inputs to be adjustably set to respective logic levels to produce a first output current to substantially match a predetermined constant current; and
a second current DAC, the second current DAC including a second reference input to receive the first output current from the first current DAC, the second current DAC including second logic inputs to be adjustably set to respective logic levels to produce a second output current to compensate for the offset voltage.

2. The apparatus of claim 1, wherein:
the position sensor circuit including the offset compensation circuitry comprises:
a buffer output circuit comprising an amplifier, the amplifier including differential inputs to receive the position signal and an output to output the position signal, the output of the amplifier coupled to one of the differential inputs via at least a feedback resistor; and
an output of the second DAC to produce the second output current, the output of the second DAC operably coupled to the other one of the differential inputs of the amplifier of the buffer output circuit.

3. The apparatus of claim 2, wherein:
the position sensor circuit including the offset compensation circuitry comprises:
a voltage divider circuit including at least first and second resistors coupled in series, the voltage divider circuit coupled between the other one of the differential inputs of the amplifier and a reference voltage; and
the output of the second DAC coupled to a node at which the first and the second resistors of the voltage divider circuit are series coupled.

4. The apparatus of claim 3, wherein:
the second current DAC includes the second logic inputs to be adjustably set to the respective logic levels to produce the second output current that produces an adjustment offset voltage at the node to substantially match or cancel the offset voltage at the output of the amplifier of the buffer output circuit.

5. The apparatus of claim 2, wherein the amplifier of the buffer output circuit comprises an operational transconductance amplifier.

6. The apparatus of claim 2, wherein:
the position sensor circuit including the offset compensation circuitry comprises:
one or more first registers in which to program and store one or more first digital values, the one or more first registers operably coupled to the first logic inputs of the first current DAC, the one or more first digital values in the one or more first registers to adjustably set the respective logic levels of the first logic inputs of the first current DAC to produce the first output current; and
one or more second registers in which to program and store one or more second digital values, the one or more second registers operably coupled to the second logic inputs of the second current DAC, the one or more second digital values in the one or more second registers to adjustably set the respective logic levels of the second logic inputs of the second current DAC to produce the second output current.

7. The apparatus of claim 2, wherein:
the position sensor circuit comprises:
an excitation circuit to generate the excitation signal to drive one or more excitation coils, the excitation signal to produce a varying magnetic field around the one or more excitation coils for inducing a sinusoidal sense signal in a sense coil, the varying magnetic field disturbed in accordance with a position of a target which modulates the sinusoidal sense signal;
an analog front-end circuit to receive and process the modulated sinusoidal sense signal; and
a demodulator circuit to demodulate the modulated sinusoidal sense signal to generate the position signal at an output, the output of the demodulator circuit coupled to the differential inputs of the amplifier of the buffer output circuit.

8. The apparatus of claim 7, wherein:
the position sensor circuit comprises:
a gain control circuitry, the gain control circuitry to adjust the amplitude of the excitation signal at least partially based on an amplitude of the position signal.

9. The apparatus of claim 7, wherein:
the position sensor circuit including the offset compensation circuitry comprises:
a current mirror circuit, the current mirror circuit coupled to the excitation circuit and the first current DAC, the current mirror circuit to mirror a tail current of the excitation circuit as the first input current at the first reference input of the first current DAC.

10. The apparatus of claim 7, wherein:
the position sensor circuit including the offset compensation circuitry comprises:
a peak detector, the peak detector to detect peak voltages of the excitation signal; and
a voltage-to-current converter, the voltage-to-current converter to convert the peak voltages of the excitation signal into the first input current at the first reference input of the first current DAC.

11. The apparatus of claim 2, comprising:
an integrated circuit (IC) including the position sensor circuit, the output of the amplifier of the buffer output circuit coupled to an output pin of the IC.

12. The apparatus of claim 11, wherein the IC excludes a central processing unit configured to execute machine-executable code.

13. An apparatus comprising:
an integrated circuit (IC) including a position sensor circuit comprising:
an excitation circuit to generate an excitation signal to drive one or more excitation coils, the excitation signal to produce a varying magnetic field around the one or more excitation coils for inducing a sinusoidal sense signal in a sense coil, the varying magnetic field disturbed in accordance with a position of a target which modulates the sinusoidal sense signal;
an analog front-end circuit to receive and process the modulated sinusoidal sense signal;
a demodulator circuit to demodulate the modulated sinusoidal sense signal to generate a position signal at an output;
a buffer output circuit comprising an amplifier, the amplifier including differential inputs operably coupled to the output of the demodulator circuit, the amplifier including an output coupled to one of the differential inputs via at least a feedback resistor, the output coupled to an output pin of the IC;
an offset compensation circuitry to compensate for an offset voltage of the position signal, the offset compensation circuitry comprising:
a first current digital-to-analog converter (DAC), the first current DAC including a first reference input to receive a first input current that varies in response to changes in amplitude of the excitation signal, the first current DAC including first logic inputs to be adjustably set to respective logic levels to produce a first output current to substantially match a predetermined constant current; and
a second current DAC, the second current DAC including a second reference input to receive the first output current from the first current DAC, the second current DAC including an output operably coupled to the other one of the differential inputs of the amplifier of the buffer output circuit, the second current DAC including second logic inputs to be adjustably set to respective logic levels to produce a second output current at the output to compensate for the offset voltage.

14. The apparatus of claim 13, wherein:
the offset compensation circuitry comprises:
a voltage divider circuit including at least first and second resistors coupled in series, the voltage divider circuit coupled between the other one of the differential inputs of the amplifier of the buffer output circuit and a reference voltage; and
the output of the second DAC coupled to a node at which the first and the second resistors of the voltage divider circuit are series coupled.

15. The apparatus of claim 14, wherein:
the offset compensation circuitry comprises:
one or more first registers in which to program and store one or more first digital values, the one or more first registers operably coupled to the first logic inputs of the first current DAC, the one or more first digital values in the one or more first registers to adjustably set the respective logic levels of the first logic inputs of the first current DAC to produce the first output current;
one or more second registers in which to program and store one or more second digital values, the one or more second registers operably coupled to the second logic inputs of the second current DAC, the one or more second digital values in the one or more second registers to adjustably set the respective logic levels of the second logic inputs of the second current DAC to produce the second output current;
wherein in the first current DAC, the first output current is produced at least partially based on the first input current at the first reference input and the adjustably set logic levels of the first logic inputs of the first current DAC; and
wherein in the second current DAC, the second output current is produced at least partially based on the first output current at the second reference input and the adjustably set logic levels of the second logic inputs of the second current DAC.

16. The apparatus of claim 13, wherein:
the position sensor circuit comprises:
a gain control circuitry, the gain control circuitry to adjust the amplitude of the excitation signal at least partially based on an amplitude of the position signal.

17. The apparatus of claim 13, wherein:
the offset compensation circuitry comprises:
a current mirror circuit, the current mirror circuit coupled to the excitation circuit and the first current DAC, the current mirror circuit to mirror a tail current of the excitation circuit as the first input current at the first reference input of the first current DAC.

18. The apparatus of claim 13, wherein:
the offset compensation circuitry comprises:
a peak detector, the peak detector to detect peak voltages of the excitation signal; and
a voltage-to-current converter, the voltage-to-current converter to convert the peak voltages of the excitation signal into the first input current.

19. The apparatus of claim 18, wherein the IC excludes a central processing unit configured to execute machine-executable code.

20. A method comprising:
at a position sensor circuit for an inductive position sensor, the position sensor circuit including an offset compensation circuitry to compensate for an offset voltage of a position signal of the inductive position sensor, the offset compensation circuitry including at least a first current digital-to-analog converter (DAC) and a second current DAC, the first current DAC including a first reference input to receive a first input current that varies in response to changes in amplitude of an excitation signal of the position sensor circuit,
receiving, in a calibration procedure via a programming interface, one or more first digital values to store in one or more first registers of the offset compensation circuitry, the one or more first registers operably coupled to first logic inputs of the first current DAC, the one or more first digital values adjustably set to produce a first output current at the first current DAC that substantially matches a predetermined constant current, the first output current received at a second reference input of the second current DAC; and
receiving, in the calibration procedure via the programming interface, one or more second digital values to store in one or more second registers of the offset compensation circuitry, the one or more second registers operably coupled to second logic inputs of the second current DAC, the one or more second digital values adjustably set to produce a second output current at the second current DAC to compensate for the offset voltage.

21. The method of claim 20, the method comprising:
prior to the calibration procedure, setting an airgap between a target and multiple coils of the inductive position sensor.

22. The method of claim 20, comprising:
at the position sensor circuit,
providing, in the calibration procedure via the programming interface, measurements of the first output current, or values corresponding thereto, responsive to adjustments to the one or more first digital values; and
providing, in the calibration procedure via the programming interface, measurements of the second output current, or values corresponding thereto, responsive to adjustments to the one or more second digital values.

23. The method of claim 20, comprising:
providing the position sensor circuit including the offset compensation circuitry, comprising:
an excitation circuit to generate the excitation signal to drive one or more excitation coils, the excitation signal to produce a varying magnetic field around the one or more excitation coils for inducing a sinusoidal sense signal in a sense coil, the varying magnetic field disturbed in accordance with a position of a target which modulates the sinusoidal sense signal;
an analog front-end circuit to receive and process the modulated sinusoidal sense signal;
a demodulator circuit to demodulate the modulated sinusoidal sense signal to generate the position signal at an output, the position signal having the offset voltage;
a gain control circuitry, the gain control circuitry to adjust the amplitude of the excitation signal at least partially based on an amplitude of the position signal;
a buffer output circuit comprising an amplifier, the amplifier including differential inputs operably coupled to the output of the demodulator circuit, the amplifier including an output coupled to one of the differential inputs via at least a feedback resistor;
a voltage divider circuit including at least first and second resistors coupled in series, the voltage divider circuit coupled between the other one of the differential inputs of the amplifier and a reference voltage; and
the output of the second current DAC coupled to a node at which the first and the second resistors of the voltage divider circuit are series coupled.

24. The method of claim 23, wherein the position sensor circuit including the offset compensation circuitry is provided in an integrated circuit (IC), the IC excluding a central processing unit configured to execute machine-executable code.

25. The method of claim 23, comprising:
at the position sensor circuit including the offset compensation circuitry,
mirroring a tail current of the excitation circuit as the first input current at the first reference input of the first current DAC.

26. The method of claim 23, wherein:
at the position sensor circuit including the offset compensation circuitry, detecting peak voltages of the excitation signal; and
converting the peak voltages of the excitation signal into the first input current at the first reference input of the first current DAC.
